(19) United States
(12) Patent Application Publication
(10) Pub. No.: US 2025/0341929 A1
(43) Pub. Date: Nov. 6, 2025

(54) ELECTRONIC DEVICE

(71) Applicant: Samsung Display Co., Ltd., Yongin-si (KR)

(72) Inventors: GAYOUNG KIM, Yongin-si (KR); SANGHYUN LIM, Yongin-si (KR)

(21) Appl. No.: 19/019,063

(22) Filed: Jan. 13, 2025

(30) Foreign Application Priority Data
May 3, 2024 (KR) 10-2024-0058958

(51) Int. Cl. G06F 3/044; G06F 3/041

(52) U.S. Cl. CPC G06F 3/0446; G06F 3/041662; G06F 3/0443; G06F 2203/04106

(57) ABSTRACT

An electronic device includes a display panel, a cover panel, and an electronic module, wherein the cover panel includes a cushion layer, a magnetic layer, and a conductive layer, a first opening is defined in the cushion layer and the magnetic layer, a second opening is defined in the conductive layer, the electronic module is located in the first opening and the second opening, and a first area adjacent to the electronic module and having a first magnetic permeability and a second area around the first area and has a second magnetic permeability different from the first magnetic permeability are defined in the cover panel.

### CROSS-REFERENCE TO RELATED APPLICATIONS

The present application claims priority to and the benefit of Korean Patent Application No. 10-2024-0058958 filed on May 3, 2024, in the Korean Intellectual Property Office, the entire disclosure of which is incorporated by reference herein.

### BACKGROUND

Embodiments of the present disclosure described herein relate to an electronic device having improved reliability.

An electronic device may include electronic modules. For example, the electronic device may be a portable terminal and/or a wearable module, and the electronic modules may include a fingerprint sensor, an antenna module, a camera module, and/or a battery module. As the portable terminal is thinned and the wearable device is miniaturized, a space on which the electronic modules are to be mounted is gradually decreased. Further, as the electronic device is developed to have more functions and high specifications, the number of electronic modules included in the electronic device is increasing.

### SUMMARY

Embodiments of the present disclosure provide an electronic device having improved reliability.

According to one or more embodiments, an electronic device includes a display panel, a cover panel under the display panel, and an electronic module under the display panel, wherein the cover panel includes a cushion layer under the display panel, a magnetic layer under the cushion layer, and a conductive layer under the magnetic layer, a first opening is defined in the cushion layer and the magnetic layer, a second opening is defined in the conductive layer, the electronic module is located in the first opening and the second opening, and a first area adjacent to the electronic module and having a first magnetic permeability and a second area around the first area and has a second magnetic permeability different from the first magnetic permeability are defined in the cover panel.

A first area of the first opening may be smaller than a second area of the second opening.

The second area may be 1.5 to 1.6 times the first area.

In a plan view, the magnetic layer may cover the conductive layer.

The magnetic layer may include ferrite, and the conductive layer may include copper.

A magnetic permeability of the magnetic layer may be higher than a magnetic permeability of the conductive layer.

In a plan view, at least a portion of the second opening may overlap the first area.

In a plan view, the electronic module may not overlap the magnetic layer and the conductive layer.

The electronic module may include a fingerprint sensor.

The electronic module may include a speaker or a photo sensor.

Each of the first opening and the second opening may have a circular shape.

Each of the first opening and the second opening may have a quadrangular shape.

The display panel may include a display layer and a sensor layer on the display layer, and wherein the sensor layer may include a plurality of first electrodes arranged along a first direction and extending in a second direction intersecting the first direction, a plurality of second electrodes arranged along the second direction and extending in the first direction, a plurality of first auxiliary electrodes arranged along the first direction, extending in the second direction, and overlapping the plurality of first electrodes, and a plurality of second auxiliary electrodes arranged along the second direction, extending in the first direction, and overlapping the plurality of second electrodes.

The magnetic layer may include a first portion in the first area and a second portion in the second area, and a magnetic permeability of the first portion may be higher than a magnetic permeability of the second portion.

Areas of the first opening and the second opening may be the same.

A first area of the first opening may be smaller than a second area of the second opening.

An area of the first portion may be 0.2 to 0.3 times an area of each of the first opening and the second opening.

In a plan view, the conductive layer may overlap only the second area, and the magnetic layer may overlap the first area and the second area.

The cover panel may further include an insulating layer at a same layer as the conductive layer and overlapping the first area in a plan view.

The cover panel may further include a sub-conductive layer under the conductive layer and including a third opening having an area larger than that of the second opening.

According to one or more embodiments, an electronic device includes a display panel and a cover panel under the display panel, wherein the cover panel includes a magnetic layer under the display panel and having a first opening, and a conductive layer under the magnetic layer and having a second opening, and a first area adjacent to the first opening and the second opening and having a first magnetic permeability and a second area around the first area and has a second magnetic permeability different from the first magnetic permeability are defined in the cover panel.

A first area of the first opening may be smaller than a second area of the second opening.

In a plan view, the magnetic layer may cover the conductive layer.

The magnetic layer may include ferrite, and the conductive layer may include copper.

The magnetic layer may include a first portion in the first area and a second portion in the second area, and a magnetic permeability of the first portion may be higher than a magnetic permeability of the second portion.

In a plan view, the conductive layer may overlap only the second area, and the magnetic layer may overlap the first area and the second area.

The display panel may include a display layer and a sensor layer on the display layer, and wherein the sensor layer may include a plurality of first electrodes arranged along a first direction and extending in a second direction intersecting the first direction, a plurality of second electrodes arranged along the second direction and extending in the first direction, a plurality of first auxiliary electrodes arranged along the first direction, extending in the second direction, and overlapping the plurality of first electrodes, and a plurality of second auxiliary electrodes arranged along the second direction, extending in the first direction, and overlapping the plurality of second electrodes.

In a plan view, the conductive layer may not overlap the first area.

The cover panel may further include an insulating layer on a same layer as the conductive layer and overlapping the first area in a plan view.

The cover panel may further include a sub-conductive layer under the conductive layer and having a third opening having an area larger than that of the second opening is defined.

### BRIEF DESCRIPTION OF THE DRAWINGS

The above and other aspects and features of the present disclosure will become apparent by describing in detail embodiments thereof with reference to the accompanying drawings.

FIG. 1 is a block diagram of an electronic device according to one or more embodiments of the present disclosure.

FIG. 2 is a perspective view of the electronic device according to one or more embodiments of the present disclosure.

FIG. 3 is a schematic cross-sectional view of the electronic device according to one or more embodiments of the present disclosure.

FIG. 4 is a schematic cross-sectional view of a display panel according to one or more embodiments of the present disclosure.

FIG. 5 is a view for describing an operation of the electronic device according to one or more embodiments of the present disclosure.

FIG. 6 is a cross-sectional view of the display panel taken along the line I-I′ of FIG. 2 according to one or more embodiments of the present disclosure.

FIG. 7 is a plan view of a sensor layer according to one or more embodiments of the present disclosure.

FIG. 8 is an enlarged plan view illustrating one sensing unit according to one or more embodiments of the present disclosure.

FIG. 9A is a plan view illustrating a first conductive layer of the sensing unit according to one or more embodiments of the present disclosure.

FIG. 9B is a plan view illustrating a second conductive layer of the sensing unit according to one or more embodiments of the present disclosure.

FIG. 9C is a cross-sectional view of the sensor layer taken along the line III-III′ illustrated in FIGS. 9A and 9B.

FIG. 10A is a plan view illustrating a first conductive layer of the sensing unit according to one or more embodiments of the present disclosure.

FIG. 10B is a plan view illustrating a second conductive layer of the sensing unit according to one or more embodiments of the present disclosure.

FIG. 10C is a cross-sectional view of the sensor layer taken along the line A-A′ illustrated in FIGS. 10A and 10B according to one or more embodiments of the present disclosure.

FIG. 11 is a view illustrating an operation of a sensor driving unit according to one or more embodiments of the present disclosure.

FIG. 12 is a view illustrating the operation of the sensor driving unit according to one or more embodiments of the present disclosure.

FIGS. 13A and 13B are views for describing a first mode according to one or more embodiments of the present disclosure.

FIG. 14 is a view for describing the first mode according to one or more embodiments of the present disclosure.

FIG. 15 is a view for describing a second mode according to one or more embodiments of the present disclosure.

FIG. 16A is a view for describing the second mode according to one or more embodiments of the present disclosure.

FIG. 16B is a view for describing the second mode based on sensing units according to one or more embodiments of the present disclosure.

FIG. 17 is a cross-sectional view of the electronic device taken along the line II-II′ of FIG. 2 according to one or more embodiments of the present disclosure.

FIG. 18 is a perspective view illustrating a portion of a cover panel and a pen according to one or more embodiments of the present disclosure.

FIG. 19 is a graph depicting an inductance for each position according to one or more embodiments of the present disclosure.

FIG. 20A is a plan view illustrating a portion of a rear surface of the cover panel according to one or more embodiments of the present disclosure.

FIG. 20B is a plan view illustrating the portion of the rear surface of the cover panel according to one or more embodiments of the present disclosure.

FIG. 21 is a cross-sectional view of the electronic device taken along a line corresponding to the line II-II′ of FIG. 2 according to one or more embodiments of the present disclosure.

FIG. 22 is a perspective view illustrating the portion of the cover panel and the pen according to one or more embodiments of the present disclosure.

FIG. 23 is a graph depicting an inductance for each position according to one or more embodiments of the present disclosure.

FIG. 24 is a cross-sectional view of the electronic device taken along a line corresponding to the line II-II′ of FIG. 2 according to one or more embodiments of the present disclosure.

FIG. 25 is a cross-sectional view of the electronic device taken along a line corresponding to the line II-II′ of FIG. 2 according to one or more embodiments of the present disclosure.

FIG. 26 is a cross-sectional view of the electronic device taken along a line

corresponding to the line II-II′ of FIG. 2 according to one or more embodiments of the present disclosure.

FIG. 27A is a perspective view of the electronic device according to one or more embodiments of the present disclosure. FIG. 27B is a rear perspective view of the electronic device according to one

or more embodiments of the present disclosure.

FIG. 28 is a cross-sectional view of the electronic device according to one or more embodiments of the present disclosure.

FIG. 29 is a cross-sectional view of an electronic device according to one or more embodiments of the present disclosure.

FIG. 30 illustrates an input sensor according to one or more embodiments of the present disclosure.

### DETAILED DESCRIPTION

In the specification, the expression that a first component (or area, layer, part, portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and/or the dimension of components are exaggerated for effective description of technical contents. The expression “and/or” includes one or more combinations which associated components are capable of defining.

Although the terms “first”, “second”, etc. may be used to describe various components, the components should not be limited by the terms. The terms are only used to distinguish one component from another component. For example, without departing from the spirit and scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, and/or components, described in the specification, or a combination thereof, and do not exclude in advance the presence or additional possibility of one or more other features, numbers, steps, operations, elements, and/or components, and/or a combination thereof.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, ±20%, ±10%, ±5% of the stated value.

In the description, the term “and/or” is intended to include any combination of

the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the description, the phrase “at least one of” is intended to include the meaning of “at least one selected from the group of” for the purpose of its meaning and interpretation. For example, “at least one of A and B” may be understood to mean “A, B, or A and B.”

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, one or more embodiment of the present disclosure will be described with reference to the accompanying drawings.

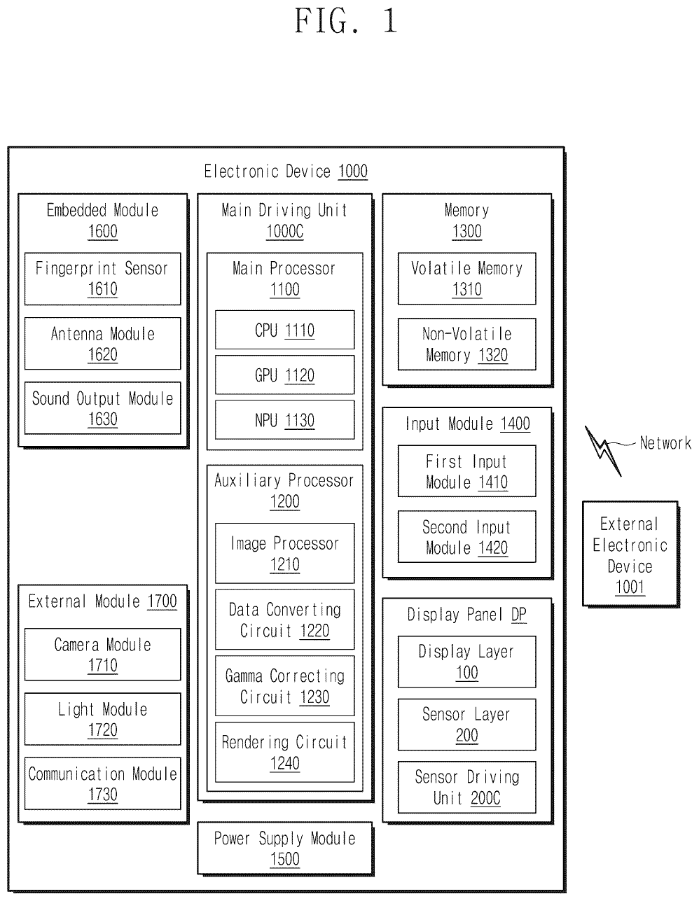

FIG. 1 is a block diagram of an electronic device according to one or more embodiments of the present disclosure.

Referring to FIG. 1, an electronic device 1000 may output various pieces of information through a display panel DP inside an operating system. When a main driving unit 1000C executes an application stored in a memory 1300, the display panel DP may provide application information to a user through a display layer 100. The main driving unit 1000C may be referred to as a host processor.

The main driving unit 1000C may acquire an external input through an input module 1400 and execute an application corresponding to the external input. For example, when the user selects a camera icon displayed on the display layer 100, the main driving unit 1000C may acquire a user input through a sensor layer 200 and a sensor driving unit 200C, and activate a camera module 1710. The main driving unit 1000C may transmit, to the display panel DP, image data corresponding to a captured image acquired through the camera module 1710. The display panel DP may display an image corresponding to the captured image through the display layer 100.

As another example, when personal information authentication is executed on the display panel DP, a fingerprint sensor 1610 may acquire input fingerprint information as input data. The main driving unit 1000C may compare input data acquired through the fingerprint sensor 1610 with authentication data stored in the memory 1300 and execute an application according to the comparison result. The display panel DP may display, through the display layer 100, information executed according to a logic of the application.

As another example, when a music streaming icon displayed on the display panel DP is selected, the main driving unit 1000C may acquire the user input through the sensor layer 200 and the sensor driving unit 200C, and activate a music streaming application stored in the memory 1300. When a music play command is input from the music streaming application, the main driving unit 1000C may activate a sound output module 1630 to provide sound information corresponding to the music play command to the user.

The operation of the electronic device 1000 has been briefly described above. Hereinafter, a configuration of the electronic device 1000 will be described in detail. Some of components of the electronic device 1000, which will be described below, may be integrated and provided as one component or one component may be provided to be separated into two or more components.

The electronic device 1000 may communicate with an external electronic device 1001 through a network (e.g., a short-range wireless communication network or a long-range wireless communication network). According to one or more embodiments, the electronic device 1000 may include the main driving unit 1000C, the memory 1300, the input module 1400, the display panel DP, a power supply module 1500, an embedded module 1600, and an external module 1700. According to one or more embodiments, in the electronic device 1000, at least one of the above-described components may be omitted, or one or more other components may be added. According to one or more embodiments, some (e.g., the fingerprint sensor 1610, an antenna module 1620, and the sound output module 1630) of the above-described components may be integrated into one other component (e.g., the display panel DP).

The main driving unit 1000C may execute software to control at least one other component (e.g., a hardware or software component) of the electronic device 1000 connected to the main driving unit 1000C and to process or calculate various pieces of data. According to one or more embodiments, as at least a portion of the processing or calculating of the data, the main driving unit 1000C may store, in a volatile memory 1310, a command or data received from other components (e.g., the input module 1400, the fingerprint sensor 1610, or a communication module 1730), may process the command or data stored in the volatile memory 1310, and may store the result data in a non-volatile memory 1320.

The main driving unit 1000C may include a main processor 1100 and an auxiliary processor 1200. The main processor 1100 may include one or more of a central processing unit (CPU) 1110 or an application processor. The main processor 1100 may further include one or more of a graphic processing unit (GPU) 1120, a communication processor (CP), and an image signal processor (ISP). The main processor 1100 may further include a neural processing unit (NPU) 1130. The NPU 1130 may be a processor that is specialized in processing an artificial intelligence model, and the artificial intelligence model may be generated through machine learning. The artificial intelligence model may include a plurality of artificial neural network layers. The artificial neural network may be one of a deep neutral network (DNN), a convolutional neural network (CNN), a recurrent neural network (RNN), a restricted boltzmann machine (RBM), a deep belief network (DBN), a bidirectional recurrent deep neural network (BRDNN), a deep Q-network, and a combination of two or more thereof, but the present disclosure is not limited to the above-described examples. The artificial intelligence model may additionally or alternatively include a software structure in addition to a hardware structure. At least two of the processing units and the processors that are described above may be implemented as one integrated component (e.g., a single chip) or may be implemented as independent components (e.g., a plurality of chips).

The auxiliary processor 1200 may include an image processing unit 1210, a data converting circuit 1220, a gamma correcting circuit 1230, and a rendering circuit 1240. The image processing unit 1210 may convert and output a data format of the image data.

The data converting circuit 1220 may receive the image data from a driving controller that drives the display layer 100 and may compensates for the image data so that an image is displayed at a desired luminance according to characteristics of the electronic device 1000 or setting of the user or may convert the image data to reduce power consumption or compensate for afterimages. The gamma correcting circuit 1230 may convert the image data, a gamma reference voltage, and/or the like so that the image displayed on the electronic device 1000 has desired gamma characteristics. The rendering circuit 1240 may receive the image data from the driving controller and render the image data in consideration of a pixel arrangement of the display layer 100 applied to the electronic device 1000, and/or the like. At least one of the data converting circuit 1220, the gamma correcting circuit 1230, and the rendering circuit 1240 may be integrated into another component (e.g., the main processor 1100 or the driving controller). At least one of the data converting circuit 1220, the gamma correcting circuit 1230, and the rendering circuit 1240 may be integrated into a data driver.

The memory 1300 may store various pieces of data used by at least one component (e.g., the main driving unit 1000C) of the electronic device 1000 and input data or output data for a command related thereto. The memory 1300 may include at least one of the volatile memory 1310 and the non-volatile memory 1320.

The input module 1400 may receive, from the outside (e.g., the user or an external electronic device 1001) of the electronic device 1000, commands or data to be used in the components (e.g., the main driving unit 1000C, the sensor layer 200, and/or the sound output module 1630) of the electronic device 1000.

The input module 1400 may include a first input module 1410 through which the commands or data are input from the user and a second input module 1420 through which the commands or data are input from the external electronic device 1001. The first input module 1410 may include a microphone, a mouse, a keyboard (e.g., a button), and/or a pen (e.g., a passive pen and/or an active pen). The second input module 1420 may support a designated protocol that may be connected to the external electronic device 1001 by wire and/or wirelessly. According to one or more embodiments, the second input module 1420 may include a high definition multimedia interface (HDMI), a universal serial bus (USB) interface, a secure digital (SD) card interface, and/or an audio interface. The second input module 1420 may include a connector that may be physically connected to the external electronic device 1001, for example, an HDMI connector, a USB connector, an SD card connector, and/or an audio connector (e.g., a headphone connector).

The display panel DP may visually provide information to the user. The display panel DP may include the display layer 100, the sensor layer 200, and the sensor driving unit 200C. The display panel DP may further include a window, a chassis, a bracket, and/or the like for protecting the display layer 100. The display panel DP may further include a light emitting driving circuit, a voltage generator, and/or the like.

The sensor layer 200 may generate data values corresponding to coordinate information of input by a human body of the user or input by the pen. A change in a capacitance caused by the input of the sensor layer 200 may be generated as the data values. The sensor layer 200 may sense input by the passive pen or transmit or receive data to or from the active pen.

The power supply module 1500 may supply power to the components of the electronic device 1000. The power supply module 1500 may include a battery that charges a power voltage. The battery may include a non-rechargeable primary cell, a rechargeable secondary cell, a fuel cell, and/or the like. The power supply module 1500 may include a power management integrated circuit (PMIC). The PMIC may supply optimized power to the above-described modules and modules which will be described below. The PMIC may supply optimized power to the above-described components and components which will be described below. The power supply module 1500 may include a wireless power transmission/reception member electrically connected to the battery. The wireless power transmission/reception member may include a plurality of coil-shaped antenna radiators.

The electronic device 1000 may further include the embedded module 1600 and the external module 1700. The embedded module 1600 may include the fingerprint sensor 1610, the antenna module 1620, and the sound output module 1630. The external module 1700 may include the camera module 1710, a light module 1720, and the communication module 1730.

The fingerprint sensor 1610 may generate a data value corresponding to a fingerprint of the user. The fingerprint sensor 1610 may include any one of an ultrasonic type fingerprint sensor, an optical type fingerprint sensor, and/or a capacitance type fingerprint sensor.

The antenna module 1620 may include one or more antennas for transmitting and/or receiving a signal or power to or from the outside. According to one or more embodiments, the communication module 1730 may transmit a signal to the external electronic device 1001 or receive a signal from the external electronic device 1001 through an antenna suitable for a communication method. An antenna pattern of the antenna module 1620 may be integrated into one component (e.g., the display layer 100 or the sensor layer 200) of the display panel DP.

The sound output module 1630 is a device to output a sound signal to the outside of the electronic device 1000, and for example, may include a speaker used for general purposes such as multimedia reproduction or recording reproduction and a receiver dedicated for receiving a call. According to one or more embodiments, the receiver may be formed integrally with or separately from the speaker. A sound output pattern of the sound output module 1630 may be integrated into the display panel DP.

The camera module 1710 may capture a still image and/or a moving image. According to one or more embodiments, the camera module 1710 may include one or more lenses, an image sensor, or an image signal processor. The camera module 1710 may further include an infrared camera that may measure the presence or absence of the user, a position of the user, a gaze of the user, and/or the like.

The light module 1720 may provide light. The light module 1720 may include a light emitting diode and/or a xenon lamp. The light module 1720 may be operated in conjunction with the camera module 1710 and/or operated independently from the camera module 1710.

The communication module 1730 may support establishing a wired and/or wireless communication channel between the electronic device 1000 and the external electronic device 1001 and performing communication through the established communication channel. The communication module 1730 may include one or all of wireless communication modules such as a cellular communication module, a short-range wireless communication module, or a global navigation satellite system (GNSS) communication module and/or wired communication modules such as a local area network (LAN) and/or a power line communication module. The communication module 1730 may communicate with the external electronic device 1001 through a short-range communication network such as Bluetooth, WiFi direct, and/or infrared data association (IrDA) and/or a long distance communication network such as a cellular network, the Internet, and/or a computer network (e.g., the LAN or a wide area network (WAN)). The various types of communication modules 1730 may be implemented as one chip or may be implemented as separate chips.

The embedded module 1600, the external module 1700, and/or the like may be utilized for controlling an operation of the display panel DP in conjunction with the main driving unit 1000C.

The main driving unit 1000C may output the commands or data to the display layer 100, the sound output module 1630, the camera module 1710, and/or the light module 1720 based on input data received from the sensor layer 200. For example, the main driving unit 1000C may generate image data in response to input data applied through a mouse, a pen, and/or the like to output the generated image data to the display layer 100 and/or may generate command data in response to the input data to output the generated command data to the camera module 1710 or the light module 1720. When no input data is received from the input module 1400 for a certain period of time, the main driving unit 1000C may switch an operation mode of the electronic device 1000 to a low-power mode or a sleep mode to reduce power consumed in the electronic device 1000.

Some of the components may be connected to each other through communication methods between peripheral devices, for example, a bus, a general purpose input/output (GPIO), a serial peripheral interface (SPI), a mobile industry processor interface (MIPI), or an ultra-path interconnect (UPI) link and may exchange a signal (e.g., commands or data) between each other. The main driving unit 1000C may communicate with the display panel DP through a mutually promised interface, and for example, may use any one of the above-described communication methods, and the present disclosure is not limited to the above-described communication methods.

The electronic device 1000 according to one or more embodiments disclosed in the present disclosure may be various types of devices. The electronic device 1000 may include, for example, at least one of a portable communication device (e.g., a smart phone), a computer device, a portable multimedia device, a portable medical device, a camera, a wearable device, and/or a home appliance. The electronic device 1000 according to one or more embodiments of the present disclosure is not limited to the above-described devices.

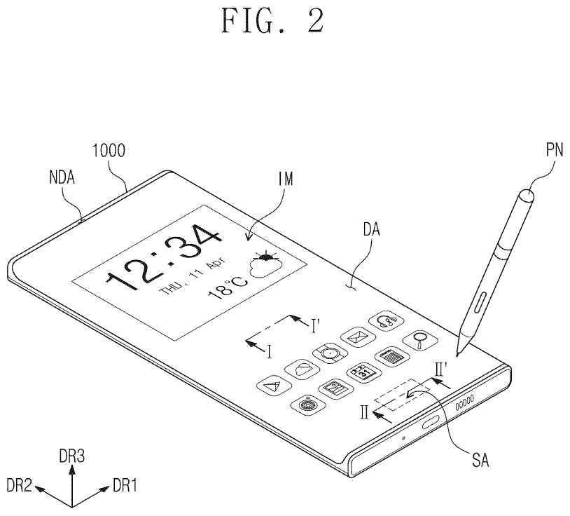

FIG. 2 is a perspective view of the electronic device according to one or more embodiments of the present disclosure.

Referring to FIG. 2, the electronic device 1000 may sense an input by an input device PN. The electronic device 1000 may be a device that is activated according to an electric signal. For example, the electronic device 1000 may be a mobile phone, a tablet, a car navigation system, a game console, and/or a wearable device, but the present disclosure is not limited thereto. FIG. 2 illustrates as an example that the electronic device 1000 is a mobile phone.

An active area DA and a peripheral area NDA may be defined in the electronic device 1000.

The active area DA may include a plane defined by a first direction DR1 and a second direction DR2. The electronic device 1000 may display an image IM in a third direction DR3 that intersects the first direction DR1 and the second direction DR2, through the active area DA. A sensing area SA may be defined in the active area DA. The electronic device 1000 may recognize biometric information of the user through the sensing area SA.

The peripheral area NDA may be around (e.g., may surround) a periphery of the active area DA.

The electronic device 1000 may sense inputs applied from the outside of the electronic device 1000. The inputs applied from the outside may include various types of external inputs such as a portion of the human body of the user, a light, heat, or pressure. The inputs applied from the outside may be referred to as second inputs.

The electronic device 1000 illustrated in FIG. 2 may sense an input by a touch of the user and an input by the input device PN. The input device PN may mean a device other than the human body of the user. The input by the input device PN may be referred to as a first input. For example, the input device PN may be an active electrostatic (AES) pen, an electro-magnetic resonance (EMR) pen, a stylus pen, a touch pen, or an electronic pen. Hereinafter, a case in which the input device PN is the EMR pen will be described as an example. The input device PN may be referred to as a pen PN.

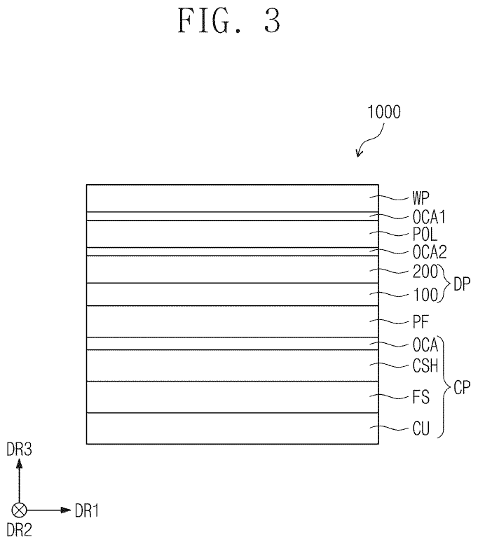

FIG. 3 is a schematic cross-sectional view of the electronic device according to one or more embodiments of the present disclosure.

Referring to FIG. 3, the electronic device 1000 may include a window WP, a plurality of adhesive layers OCA1, OCA2, and OCA, a reflection preventing layer POL, the display panel DP, a protective film PF, and a cover panel CP.

The window WP may constitute an external appearance of the electronic device 1000. The window WP may protect internal components of the electronic device 1000 from external impacts and may substantially provide the active area DA (see FIG. 2) of the electronic device 1000. For example, the window WP may include a glass substrate, a sapphire substrate, and/or a plastic film. The window WP may have a multi-layer or single-layer structure. For example, the window WP may have a laminated structure of a plurality of plastic films coupled with an adhesive or have a laminated structure of a glass substrate and a plastic film coupled with an adhesive.

The first adhesive layer OCA1 may be disposed below the window WP. The window WP and the reflection preventing layer POL may be coupled to each other by the first adhesive layer OCA1. The first adhesive layer OCA1 may include a general adhesive and/or a sticking agent. For example, the first adhesive layer OCA1 may be an optically clear adhesive film, an optically clear resin, and/or a pressure sensitive adhesive film.

The reflection preventing layer POL may be disposed under the window WP. The reflection preventing layer POL may reduce a reflectance of a natural light (or sunlight) input from an upper side of the window WP.

The reflection preventing layer POL according to one or more embodiments of the present disclosure may include a retarder and/or a polarizer. The retarder may be of a film type and/or a liquid crystal coating type and may include a λ/2 retarder and/or a λ/4 retarder. The polarizer may be of a film type and/or a liquid crystal coating type. The film type may include a stretchable synthetic resin film, and the liquid crystal coating type may include liquid crystals arranged in a suitable form (e.g., a predetermined form). The retarder and the polarizer may further include a protective film. The retarder and the polarizer themselves or the protective films may be defined as a base layer of the reflection preventing layer POL.

The second adhesive layer OCA2 may be disposed under the reflection preventing layer POL. The reflection preventing layer POL and the display panel DP may be coupled to each other by the second adhesive layer OCA2. The second adhesive layer OCA2 may include substantially the same material as that of the first adhesive layer OCA1.

The display panel DP may include the display layer 100 and the sensor layer 200.

The sensor layer 200 may be disposed under the reflection preventing layer POL. The sensor layer 200 may acquire coordinate information of an external input. The sensor layer 200 may sense an input by the input device PN (see FIG. 2). The sensor layer 200 according to one or more embodiments of the present disclosure may be directly disposed on one surface of the display layer 100. For example, the sensor layer 200 may be integrally formed with the display layer 100 in an on-cell manner. The sensor layer 200 may be manufactured through a continuous process together with the display layer 100. However, the present disclosure is not limited thereto, and the sensor layer 200 may be manufactured through a separate process and adhered to the display layer 100.

The display layer 100 may be disposed under the sensor layer 200. The display layer 100 may substantially generate the image IM (see FIG. 2). The display layer 100 may be a light emitting display layer, but the present disclosure is not particularly limited thereto. For example, the display layer 100 may include an organic light emitting display layer, a quantum dot display layer, a micro light emitting diode (LED) display layer, or a nano LED display layer. A light emitting layer of the organic light emitting display layer may include an organic light emitting material. A light emitting layer of the quantum dot display layer may include a quantum dot and a quantum rod. A light emitting layer of the micro LED display layer may include a micro LED. A light emitting layer of the nano LED display layer may include a nano LED.

The protective film PF may be disposed under the display panel DP. The protective film PF may protect a lower surface of the display layer 100. The protective film PF may include polyethylene terephthalate (PET). However, a material of the protective film PF is not particularly limited thereto.

The cover panel CP may be disposed under the protective film PF. The cover panel CP may include a first adhesive layer OCA, a cushion layer CSH, a magnetic layer FS, and a conductive layer CU.

The adhesive layer OCA may attach the cushion layer CSH and the protective film PF. The adhesive layer OCA may include a general adhesive and/or a sticking agent. For example, the first adhesive layer OCA may be an optically clear adhesive film, an optically clear resin, and/or a pressure sensitive adhesive film.

A cushion layer CSH may be disposed under the adhesive layer OCA. The cushion layer CSH may include an embossed sheet and a cushion sheet. A magnetic layer FS may be disposed under the cushion layer CSH. A conductive layer CU may be disposed under the magnetic layer FS. A description of a configuration of the cover panel CP will be described below.

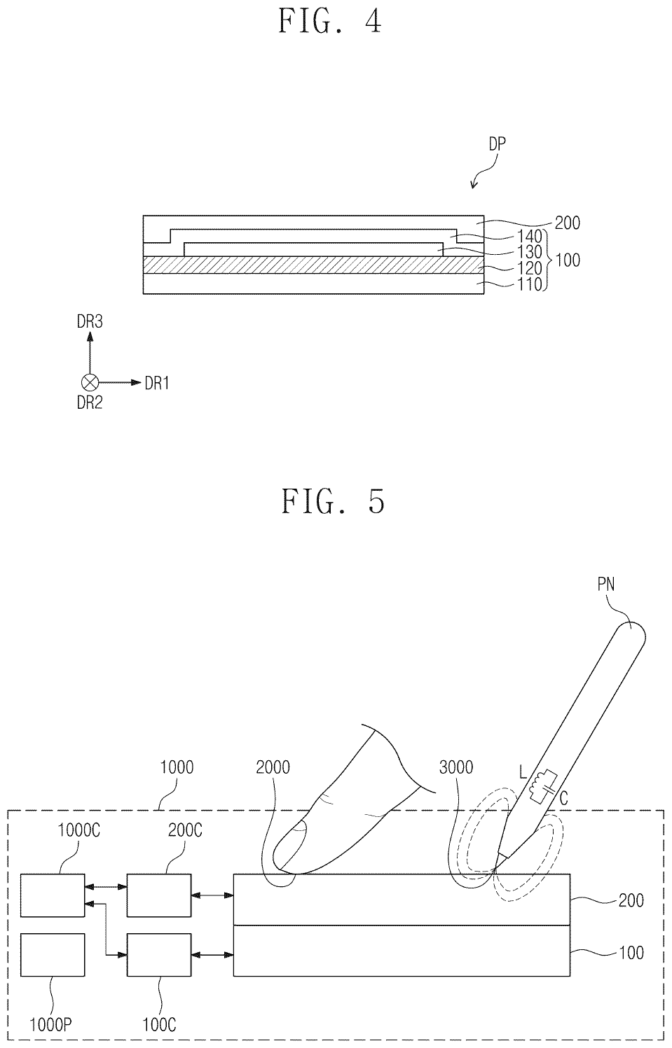

FIG. 4 is a schematic cross-sectional view of a display panel according to one or more embodiments of the present disclosure.

Referring to FIG. 4, the display panel DP may include the display layer 100 and the sensor layer 200.

The display layer 100 may include a base layer 110, a circuit layer 120, a light emitting element layer 130, and an encapsulation layer 140.

The base layer 110 may be a member that provides a base surface on which the circuit layer 120 is disposed. The base layer 110 may have a multi-layer structure or a single-layer structure. The base layer 110 may be a glass substrate, a metal substrate, a silicon substrate, a polymer substrate, and/or the like, but the present disclosure is not limited thereto.

The circuit layer 120 may be disposed on the base layer 110. The circuit layer 120 may include an insulating layer, a semiconductor pattern, a conductive pattern, a signal line, and/or the like. The insulating layer, a semiconductor layer, and a conductive layer are formed on the base layer 110 in a manner such as coating and deposition, and the insulating layer, the semiconductor layer, and the conductive layer may be selectively patterned through a plurality of photolithography processes.

The light emitting element layer 130 may be disposed on the circuit layer 120. The light emitting element layer 130 may include a light emitting element. For example, the light emitting element layer 130 may include an organic light emitting material, an inorganic light emitting material, an organic-inorganic light emitting material, a quantum dot, a quantum rod, a micro-LED, and/or a nano-LED.

The encapsulation layer 140 may be disposed on the light emitting element layer 130. The encapsulation layer 140 may protect the light emitting element layer 130 from moisture, oxygen, and/or foreign substances such as dust particles.

The sensor layer 200 may be disposed on the display layer 100. The sensor layer 200 may sense an external input applied from an external unit. The sensor layer 200 may be an integrated sensor formed continuously during a process of manufacturing the display layer 100 or the sensor layer 200 may be an external sensor attached to the display layer 100. The sensor layer 200 may be referred to as a sensor, an input sensing layer, an input sensing panel, an electronic device for sensing input coordinates, and/or the like.

According to one or more embodiments of the present disclosure, the sensor layer 200 may sense both inputs for a passive type input means such as the human body of the user and the input device PN (see FIG. 2) that generates a magnetic field having a suitable resonant frequency (e.g., a predetermined resonant frequency).

FIG. 5 is a view for describing an operation of the electronic device according to one or more embodiments of the present disclosure.

Referring to FIG. 5, the electronic device 1000 may include the display layer 100, the sensor layer 200, a display driving unit 100C, the sensor driving unit 200C, the main driving unit 1000C, and a power circuit 1000P.

The sensor layer 200 may sense a first input 2000 and/or a second input 3000 applied from an external unit. The first input 2000 and the second input 3000 may be input means that may provide a change in a capacitance of the sensor layer 200 and/or may be input means that may cause an induced current in the sensor layer 200. For example, the first input 2000 may be a passive-type input means such as the human body of the user. The second input 3000 may be an input by the pen PN or an input by a radio frequency integrated circuit (RFIC) tag. For example, the pen PN may be a passive pen or an active pen.

In one or more embodiments of the present disclosure, the pen PN may be a device that generates a magnetic field having a suitable resonant frequency (e.g., a predetermined resonant frequency). The pen PN may be configured to transmit an output signal based on an electromagnetic resonance method. The pen PN may be referred to as an input device, an input pen, a magnetic pen, a stylus pen, and/or an electromagnetic resonance pen.

The pen PN may include an RLC resonant circuit, and the RLC resonant circuit may include an inductor “L” and a capacitor “C.” In one or more embodiments of the present disclosure, the RLC resonant circuit may be a variable resonant circuit having a variable resonant frequency. In this case, the inductor “L” may be a variable inductor and/or the capacitor “C” may be a variable capacitor, but the present disclosure is not limited thereto.

The inductor “L” generates a current by a magnetic field formed in the sensor layer 200. However, the present disclosure is not particularly limited thereto. For example, when the pen PN operates as an active type, the pen PN may generate a current even when the pen PN does not receive a magnetic field from an external unit. The generated current is transmitted to the capacitor “C.” The capacitor “C” charges a current input from the inductor “L” and discharges the charged current to the inductor “L.” Thereafter, the inductor “L” may emit a magnetic field having a resonant frequency. The induced current may flow in the sensor layer 200 by the magnetic field emitted by the pen PN, and the induced current may be transmitted to the sensor driving unit 200C as a reception signal (or a sensing signal).

The main driving unit 1000C may control an overall operation of the electronic device 1000. For example, the main driving unit 1000C may control operations of the display driving unit 100C and the sensor driving unit 200C. The main driving unit 1000C may include at least one microprocessor and may further include a graphic controller. The main driving unit 1000C may be referred to as an application processor, a central processing unit (CPU), or a main processor.

The display driving unit 100C may drive the display layer 100. The display driving unit 100C may receive image data and a control signal from the main driving unit 1000C. The control signal may include various signals. For example, the control signal may include an input vertical synchronization signal, an input horizontal synchronization signal, a main clock, a data enable signal, and/or the like.

The sensor driving unit 200C may drive the sensor layer 200. The sensor driving unit 200C may receive the control signal from the main driving unit 1000C. The control signal may include a clock signal of the sensor driving unit 200C. Further, the control signal may further include a mode determining signal that determines driving modes of the sensor driving unit 200C and the sensor layer 200.

The sensor driving unit 200C may be implemented as an integrated circuit (IC) and electrically connected to the sensor layer 200. For example, the sensor driving unit 200C may be directly mounted on a suitable area (e.g., a predetermined area) of the display panel or mounted on a separate printed circuit board (PCB) using a chip on film (COF) method and electrically connected to the sensor layer 200.

The sensor driving unit 200C and the sensor layer 200 may be selectively operated in a first mode and/or a second mode. For example, the first mode may be a mode for sensing a touch input, for example, the first input 2000. The second mode may be a mode for sensing the input by the pen PN, for example, the second input 3000. The first mode may be referred to as a touch sensing mode, and the second mode may be referred to as a pen sensing mode.

Switching between the first mode and the second mode may be performed in various manners. For example, the sensor driving unit 200C and the sensor layer 200 may be driven in the first mode and the second mode in a time division manner and may sense the first input 2000 and the second input 3000. Alternatively, the switching between the first mode and the second mode may be generated by selection by the user or by a specific action of the user, any one of the first mode and the second mode may be activated or deactivated by activating or deactivating a specific application, or a current mode may be switched from one to the other one of the first mode and the second mode. Alternatively, while the sensor driving unit 200C and the sensor layer 200 are alternately operated in the first mode and the second mode, when the first input 2000 is sensed, the first mode is maintained or when the second input 3000 is sensed, the second mode is maintained.

The sensor driving unit 200C may calculate coordinate information of the input based on a signal received from the sensor layer 200 and provide a coordinate signal having the coordinate information to the main driving unit 1000C. The main driving unit 1000C executes an operation corresponding to the input of the user based on the coordinate signal. For example, the main driving unit 1000C may operate the display driving unit 100C so that a new application image is displayed on the display layer 100.

The power circuit 1000P may include a power management integrated circuit (PMIC). The power circuit 1000P may generate a plurality of driving voltages for driving the display layer 100, the sensor layer 200, the display driving unit 100C, and the sensor driving unit 200C. For example, the plurality of driving voltages may include a gate-high voltage, a gate-low voltage, a first driving voltage (e.g., an ELVSS voltage), a second driving voltage (e.g., an ELVDD voltage), an initialization voltage, and/or the like, but the present disclosure is not particularly limited to the above example. The power circuit 1000P may be included in the power supply module 1500 (see FIG. 1).

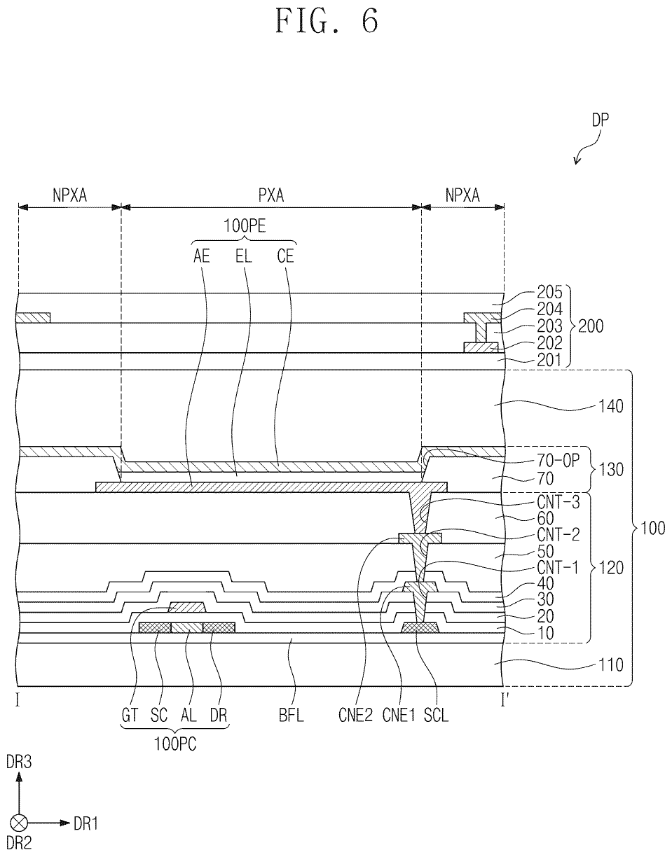

FIG. 6 is a cross-sectional view of the display panel taken along the line I-I′ of FIG. 2 according to one or more embodiments of the present disclosure. In the description of FIG. 6, the components described through FIG. 4 are designated by the same reference numerals, and a description thereof will be omitted.

Referring to FIG. 6, at least one buffer layer BFL is formed on an upper surface of the base layer 110. The buffer layer BFL may improve a coupling force between the base layer 110 and the semiconductor pattern. The buffer layer BFL may be formed in multiple layers. Alternatively, the display layer 100 may further include a barrier layer. The buffer layer BFL may include silicon oxide, silicon nitride, and/or silicon oxynitride. For example, the buffer layer BFL may include a structure in which silicon oxide layers and silicon nitride layers are alternately laminated.

Semiconductor patterns SC, AL, DR, and SCL may be arranged on the buffer layer BFL. The semiconductor patterns SC, AL, DR, and SCL may include polysilicon. However, the present disclosure is not limited thereto, and the semiconductor patterns SC, AL, DR, and SCL may also include an amorphous silicon, a low-temperature polycrystalline silicon, and/or an oxide semiconductor.

FIG. 6 illustrates some of the semiconductor patterns SC, AL, DR, and SCL, and the semiconductor pattern may be further arranged in other areas. The semiconductor patterns SC, AL, DR, and SCL may be arranged in a specific rule across pixels. The semiconductor patterns SC, AL, DR, and SCL may have different electrical properties depending on whether or not the semiconductor patterns SC, AL, DR, and SCL are doped. The semiconductor patterns SC, AL, DR, and SCL may include the first areas SC, DR, and SCL having high conductivity and the second area AL having low conductivity. The first areas SC, DR, and SCL may be doped with an N-type dopant or a P-type dopant. A P-type transistor may include a doped area doped with the P-type dopant, and an N-type transistor may include a doped area doped with the N-type dopant. The second area AL may be a non-doped area or may be an area doped at a concentration that is lower than a concentration of the first area.

A conductivity of the first areas SC, DR, and SCL may be greater than a conductivity of the second area AL, and the first areas SC, DR, and SCL may substantially serve as an electrode or a signal line. The second area AL may substantially correspond to an active area AL (or a channel) of a transistor 100PC. In other words, some AL of the semiconductor patterns SC, AL, DR, and SCL may be the active area AL of the transistor 100PC, other ones SC and DR thereof may be a source area SC or a drain area DR of the transistor 100PC, and the other one SCL thereof may be a connection electrode or a connection signal line SCL.

Each of pixels may have an equivalent circuit including seven transistors, one capacitor, and a light emitting element, and the equivalent circuit of the pixel may be modified into various forms. FIG. 6 illustrates the one transistor 100PC and one light emitting element 100PE included in the pixel, as an example.

The source area SC, the active area AL, and the drain area DR of the transistor 100PC may be formed from the semiconductor patterns SC, AL, DR, and SCL. The source area SC and the drain area DR may extend from the active area AL in opposite directions on a cross section. FIG. 6 illustrates a portion of the connection signal line SCL formed from the semiconductor patterns SC, AL, DR, and SCL. In one or more embodiments, the connection signal line SCL may be connected to the drain area DR of the transistor 100PC on a plane.

A first insulating layer 10 may be disposed on the buffer layer BFL. The first insulating layer 10 may commonly overlap the plurality of pixels and cover the semiconductor patterns SC, AL, DR, and SCL. The first insulating layer 10 may be an inorganic layer and/or an organic layer and may have a single-layer structure or a multi-layer structure. The first insulating layer 10 may include at least one of an aluminum oxide, a titanium oxide, a silicon oxide, a silicon nitride, a silicon oxy nitride, a zirconium oxide, and/or a hafnium oxide. In one or more embodiments, the first insulating layer 10 may be a single-layer silicon oxide layer. The first insulating layer 10 and an insulating layer of the circuit layer 120, which will be described below, may be an inorganic layer and/or an organic layer, and may have a single-layer structure or a multi-layer structure. The inorganic layer may include at least one of the above-described materials, but the present disclosure is not limited thereto.

A gate GT of the transistor 100PC is disposed on the first insulating layer 10. The gate GT may be a portion of a metal pattern. The gate GT overlaps the active area AL in the third direction DR3 (e.g., the thickness direction of the base layer 110). In a process of doping or reducing the semiconductor patterns SC, AL, DR, and SCL, the gate GT may function as a mask.

A second insulating layer 20 may be disposed on the first insulating layer 10 and cover the gate GT. The second insulating layer 20 may commonly overlap the pixels. The second insulating layer 20 may be an inorganic layer and/or an organic layer and may have a single-layer structure or a multi-layer structure. The second insulating layer 20 may include silicon oxide, silicon nitride, and/or silicon oxynitride. In one or more embodiments, the second insulating layer 20 may have a multi-layer structure including a silicon oxide layer and a silicon nitride layer.

A third insulating layer 30 may be disposed on the second insulating layer 20. The third insulating layer 30 may have a single-layer structure or a multi-layer structure. For example, the third insulating layer 30 may have a multi-layer structure including a silicon oxide layer and a silicon nitride layer.

A first connection electrode CNE1 may be disposed on the third insulating layer 30. The first connection electrode CNE1 may be connected to the connection signal line SCL through a contact hole CNT-1 passing through the first insulating layer 10, the second insulating layer 20, and the third insulating layer 30.

A fourth insulating layer 40 may be disposed on the third insulating layer 30 covering the first connection electrode CNE1. The fourth insulating layer 40 may be a single-layer silicon oxide layer. A fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be connected to the first connection electrode CNE1 through a contact hole CNT-2 passing through the fourth insulating layer 40 and the fifth insulating layer 50.

A sixth insulating layer 60 may be disposed on the fifth insulating layer 50 to cover the second connection electrode CNE2. The sixth insulating layer 60 may be an organic layer.

The light emitting element layer 130 may be disposed on the circuit layer 120. The light emitting element layer 130 may include the light emitting element 100PE. For example, the light emitting element layer 130 may include an organic light emitting material, an inorganic light emitting material, an organic-inorganic light emitting material, a quantum dot, a quantum rod, a micro-LED, and/or a nano-LED. Hereinafter, it will be described that the light emitting element 100PE is an organic light emitting element, but the present disclosure is not particularly limited thereto.

The light emitting element 100PE may include a first electrode AE, a light emitting layer EL, and a second electrode CE.

The first electrode AE may be disposed on the sixth insulating layer 60. The first electrode AE may be connected to the second connection electrode CNE2 through a contact hole CNT-3 passing through the sixth insulating layer 60.

A pixel defining film 70 may be disposed on the sixth insulating layer 60 and cover a portion of the first electrode AE. An opening 70-OP is defined in the pixel defining film 70. The opening 70-OP of the pixel defining film 70 exposes at least a portion of the first electrode AE.

The active area DA (see FIG. 1) may include a light emitting area PXA and a non-light emitting area NPXA adjacent to the light emitting area PXA. The non-light emitting area NPXA may be around (e.g., may surround) the light emitting area PXA. In one or more embodiments, the light emitting area PXA is defined to correspond to a partial area of the first electrode AE, which is exposed by the opening 70-OP.

The light emitting layer EL may be disposed on the first electrode AE. The light emitting layer EL may be disposed in an area corresponding to the opening 70-OP. That is, the light emitting layer EL may be formed separately from the respective pixels PX. When the light emitting layer EL is formed separately from each of the pixels, each of the light emitting layers EL may emit a light having at least one of a blue color, a red color, and/or a green color. However, the present disclosure is not limited thereto, and the light emitting layers EL may be connected to the pixels and may be commonly included in the pixels. In this case, the light emitting layer EL may also provide a blue light or a white light.

The second electrode CE may be disposed on the light emitting layer EL. The second electrode CE may have an integral shape and may be commonly included in the plurality of pixels.

In one or more embodiments of the present disclosure, a hole control layer may be disposed between the first electrode AE and the light emitting layer EL. The hole control layer may be commonly disposed in the light emitting area PXA and the non-light emitting area NPXA. The hole control layer may include a hole transport layer and may further include a hole injection layer. An electron control layer may be disposed between the light emitting layer EL and the second electrode CE. The electron control layer may include an electron transport layer and may further include an electron injection layer. The hole control layer and the electron control layer may be commonly formed in the plurality of pixels by using an open mask or an inkjet process.

The encapsulation layer 140 may be disposed on the light emitting element layer 130. The encapsulation layer 140 may include an inorganic layer, an organic layer, and an inorganic layer that are sequentially laminated, and layers constituting the encapsulation layer 140 are not limited thereto. The inorganic layers may protect the light emitting element layer 130 from moisture and/or oxygen, and the organic layer may protect the light emitting element layer 130 from foreign substances such as dust particles. The inorganic layers may include a silicon nitride layer, a silicon oxynitride layer, a silicon oxide layer, a titanium oxide layer, an aluminum oxide layer and/or the like. The organic layer may include an acryl-based organic layer, however, the present disclosure is not limited thereto.

The sensor layer 200 may include a base layer 201, a first conductive layer 202, a sensing insulating layer 203, a second conductive layer 204, and a cover insulating layer 205.

The base layer 201 may be an inorganic layer including silicon nitride, silicon oxynitride, and/or a silicon oxide. Alternatively, the base layer 201 may be an organic layer including an epoxy resin, an acryl-based resin, and/or an imide-based resin. The base layer 201 may have a single-layer structure or have a multi-layer structure in which layers are laminated in the third direction DR3.

Each of the first conductive layer 202 and the second conductive layer 204 may have a single-layer structure or have a multi-layer structure in which layers are laminated in the third direction DR3.

Each of the first conductive layer 202 and the second conductive layer 204 having a single-layer structure may include a metal layer and/or a transparent conductive layer. The metal layer may include molybdenum, silver, titanium, copper, aluminum, and/or alloys thereof. The transparent conductive layer may include a transparent conductive oxide such as an indium tin oxide (ITO), an indium zinc oxide (IZO), a zinc oxide (ZnO), and/or an indium zinc tin oxide (IZTO). In addition, the transparent conductive layer may include a conductive polymer such as poly (3,4-ethylenedioxythiophene) (PEDOT), a metal nanowire, graphene, and/or the like.

Each of the first conductive layer 202 and the second conductive layer 204 having a multi-layer structure may include metal layers. The metal layers may have, for example, a three-layer structure of titanium/aluminum/titanium. The conductive layer having a multi-layer structure may include at least one metal layer and at least one transparent conductive layer.

At least one of the sensing insulating layer 203 and the cover insulating layer 205 may include an inorganic film. The inorganic film may include aluminum oxide, titanium oxide, silicon oxide, silicon nitride, silicon oxynitride, zirconium oxide, and/or hafnium oxide.

At least one of the sensing insulating layer 203 and/or the cover insulating layer 205 may include an organic film. The organic film may include an acryl-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and/or a perylene-based resin.

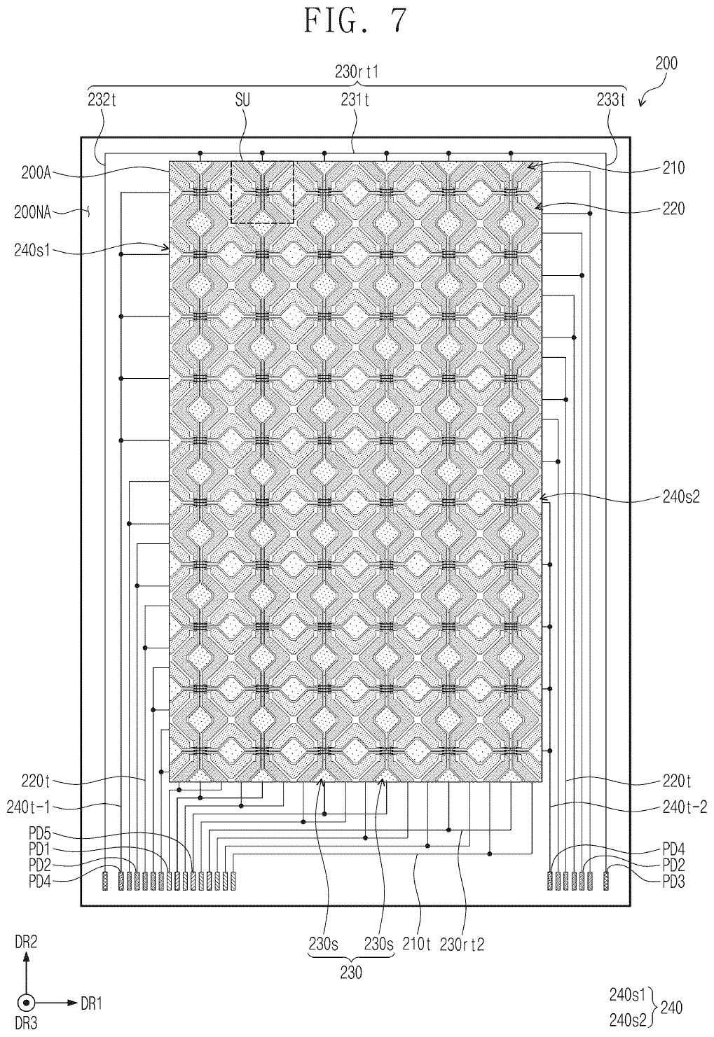

FIG. 7 is a plan view of a sensor layer according to one or more

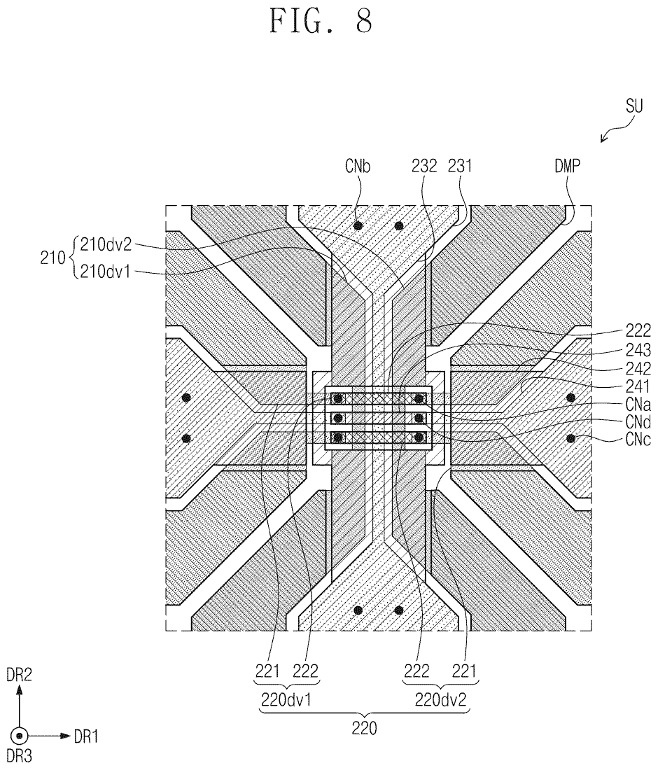

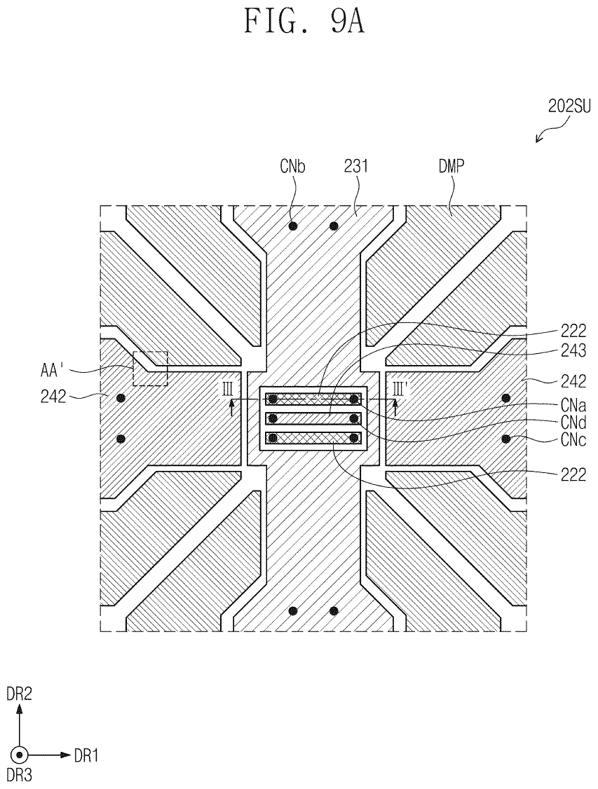

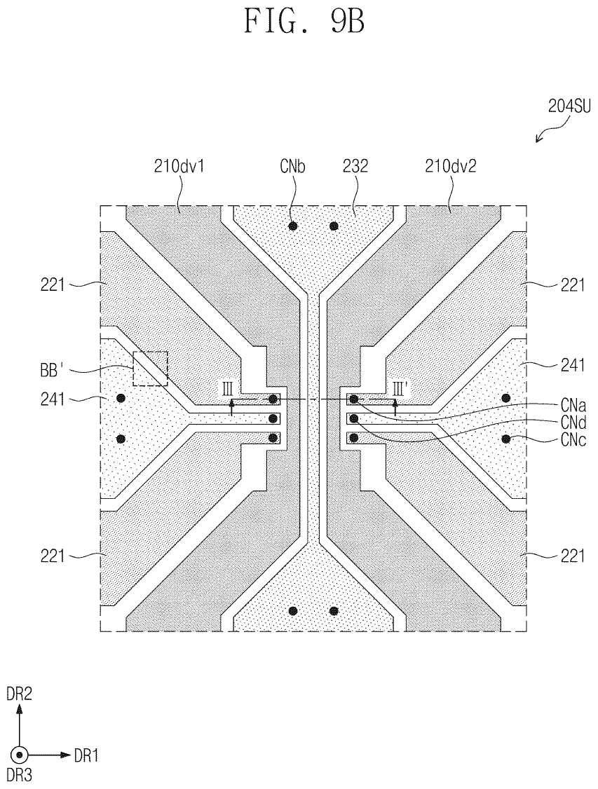

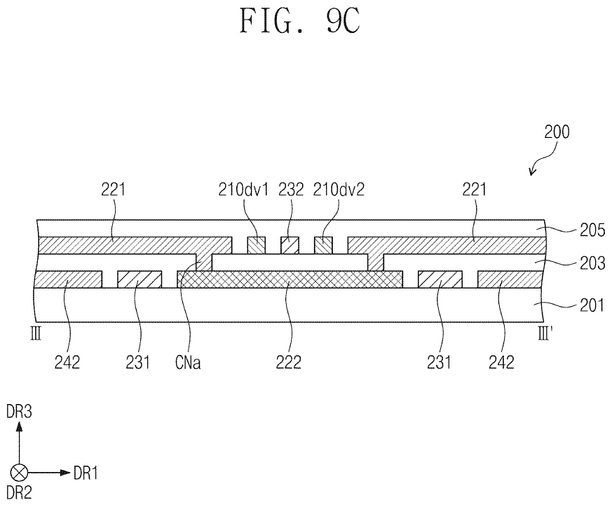

embodiments of the present disclosure, and FIG. 8 is an enlarged plan view illustrating one sensing unit according to one or more embodiments of the present disclosure. FIG. 9A is a plan view illustrating a first conductive layer of the sensing unit according to one or more embodiments of the present disclosure, FIG. 9B is a plan view illustrating a second conductive layer of the sensing unit according to one or more embodiments of the present disclosure, and FIG. 9C is a cross-sectional view of the sensor layer taken along the line III-III′ illustrated in FIGS. 9A and 9B.

Referring to FIGS. 7-9C, an active area 200A and a peripheral area 200NA adjacent to the active area 200A may be defined in the sensor layer 200.

A plurality of sensing units SU arranged in the active area 200A may be defined in the sensor layer 200. The plurality of sensing units SU may be arranged along the first direction DR1 and the second direction DR2.

The sensor layer 200 may include a plurality of first electrodes 210, a plurality of second electrodes 220, a plurality of third electrodes 230, and a plurality of fourth electrodes 240.

The plurality of first electrodes 210 may intersect the plurality of second electrodes 220. Each of the plurality of first electrodes 210 may extend in the second direction DR2. The plurality of first electrodes 210 may be spaced (e.g., spaced apart) from each other in the first direction DR1.

Each of the plurality of second electrodes 220 may extend in the first direction DR1. The plurality of second electrodes 220 may be arranged to be spaced apart from each other in the second direction DR2.

The sensing unit SU of the sensor layer 200 may be an area in which the one first electrode 210 and the one second electrode 220 intersect each other.

The sensing unit SU may include the one first electrode 210 from among the plurality of first electrodes 210, the one second electrode 220 from among the plurality of second electrodes 220, the one third electrode 230 from among the plurality of third electrodes 230, and the one fourth electrode 240 from among the plurality of fourth electrodes 240.

Each of the first electrodes 210 may include first split electrodes 210dv1 and 210dv2. The first split electrodes 210dv1 and 210dv2 may extend in the second direction DR2 and may be spaced (e.g., spaced apart) from each other in the first direction DR1. The first split electrodes 210dv1 and 210dv2 may have a shape line-symmetrical to a line extending in the second direction DR2.

Each of the second electrodes 220 may include second split electrodes 220dv1 and 220dv2. The second electrodes 220 may extend in the first direction DR1 and may be spaced (e.g., spaced apart) from each other in the second direction DR2. The second split electrodes 220dv1 and 220dv2 may have a shape line-symmetrical to a line extending in the first direction DR1.

Each of the second split electrodes 220dv1 and 220dv2 may include a sensing pattern 221 and a bridge pattern 222. The sensing pattern 221 and the bridge pattern 222 may be arranged on different layers, and the sensing pattern 221 and the bridge pattern 222 may be electrically connected to each other through a first contact CNa. For example, the bridge pattern 222 may be included in a first conductive layer 202SU, and the sensing pattern 221 and the first split electrodes 210dv1 and 210dv2 may be included in a second conductive layer 204SU. The first conductive layer 202SU may be included in the first conductive layer 202 of FIG. 6, and the second conductive layer 204SU may be included in the second conductive layer 204 of FIG. 6.

Each of the third electrodes 230 may extend in the second direction DR2, and the third electrodes 230 may be spaced (e.g., spaced apart) from each other in the first direction DR1. In one or more embodiments of the present disclosure, each of the third electrodes 230 may include a plurality of first auxiliary electrodes 230s that are connected in parallel to each other. The number of first auxiliary electrodes 230s included in each of the third electrodes 230 may be variously modified. For example, as the number of first auxiliary electrodes 230s included in each of the third electrodes 230 is increased, a resistance of each of the third electrodes 230 is decreased, and thus power efficiency may be improved, and sensing sensitivity may be improved. In contrast, as the number of first auxiliary electrodes 230s included in each of the third electrodes 230 is decreased, a loop coil pattern formed using the third electrodes 230 may be implemented in more various forms.

FIG. 7 illustrates as an example that the one third electrode 230 includes the two first auxiliary electrodes 230s, but the present disclosure is not particularly limited thereto. The first auxiliary electrodes 230s may be arranged in one-to-one correspondence with the first electrode 210. Thus, the one sensing unit SU may include a portion of the one first auxiliary electrode 230s.

A coupling capacitor may be defined between the one first electrode 210 and the one first auxiliary electrode 230s. In this case, an induced current generated during pen sensing may be transmitted from the first auxiliary electrode 230s to the first electrode 210 through the coupling capacitor. That is, the first auxiliary electrode 230s may serve to supplement a signal transmitted from the first electrode 210 to the sensor driving unit 200C. Thus, the greatest effect may be obtained when a phase of a signal induced in the first auxiliary electrode 230s and a phase of a signal induced in the first electrode 210 coincide with each other. Thus, a center of each of the first electrodes 210 in the second direction DR2 and a center of each of the first auxiliary electrodes 230s in the second direction DR2 may overlap each other. Further, a center of each of the first electrodes 210 in the first direction DR1 and a center of each of the first auxiliary electrodes 230s in the first direction DR1 may also overlap each other.

In one or more embodiments of the present disclosure, because the one third electrode 230 includes the two first auxiliary electrodes 230s, the one third electrode 230 may correspond to (or overlap) the two first electrodes 210. Thus, the number of first electrodes 210 included in the sensor layer 200 may be greater than the number of third electrodes 230. For example, the number of first electrodes 210 may be the same as a product of the number of third electrodes 230 included in the sensor layer 200 and the number of first auxiliary electrodes 230s included in each of the third electrodes 230. For example, in FIG. 7, the number of first electrodes 210 may be six, the number of third electrodes 230 may be three, and the number of first auxiliary electrodes 230s included in each of the third electrodes 230 may be two.

The fourth electrodes 240 may be arranged along the second direction DR2, and the fourth electrodes 240 may extend in the first direction DR1. In one or more embodiments of the present disclosure, each of the fourth electrodes 240 may include second auxiliary electrodes 240s1 or 240s2 that are connected in parallel to each other. The second auxiliary electrodes 240s1 or 240s2 may be referred to as a (2-1)^{th} auxiliary electrode 240s1 and a (2-2)^{th} auxiliary electrode 240s2.

Routing directions of the second auxiliary electrode 240s1 and the second

auxiliary electrode 240s2 may be different from each other. FIG. 7 illustrates the two fourth electrodes 240 and the five second auxiliary electrodes 240s1 or 240s2 included in each of the fourth electrodes 240, as an example.

In the specification, the wording that the routing directions are different from each other means that connection positions between electrodes and trace lines are different from each other. For example, a first connection position of a fourth trace line 240t-1 electrically connected to the second auxiliary electrode 240s1 and a second connection position of a fourth trace line 240t-2 electrically connected to the second auxiliary electrode 240s2 may be different from each other. The first connection position may be a leftmost end with respect to the second auxiliary electrode 240s1, and the second connection position may be a rightmost end of the second auxiliary electrode 240s2.

In one or more embodiments of the present disclosure, the sensor layer 200 may include one fourth electrode 240. In this case, the fourth electrode may include 10 second auxiliary electrodes 240s1 or 240s2 connected in parallel to each other. The number of second auxiliary electrodes 240s1 or 240s2 is merely illustrated in FIG. 7, and the number of second auxiliary electrodes 240s1 or 240s2 included in the fourth electrode is not limited to the above-described example.

FIG. 7 illustrates, as an example, that the five second auxiliary electrodes 240s1 are electrically connected to each other, and the five second auxiliary electrodes 240s2 are electrically connected to each other. That is, an area ratio of the two fourth electrodes 240 or a number ratio of the second auxiliary electrodes included in each of the two fourth electrodes 240 may be a 1:1 ratio. However, the present disclosure is not particularly limited thereto. For example, the number of second auxiliary electrodes 240s1 and the number of second auxiliary electrodes 240s2 may be different from each other.

In one or more embodiments of the present disclosure, when each of the fourth electrodes 240 includes the second auxiliary electrodes 240s1 or 240s2 connected in parallel to each other, an area of the one fourth electrode may be increased. Further, resistance of each of the fourth electrodes 240 may be decreased, thereby improving sensing sensitivity for the second input 3000 (see FIG. 6).

A coupling capacitor may be defined between the one second electrode 220 and the one second auxiliary electrode 240s1. In this case, an induced current generated during pen sensing may be transmitted from the second auxiliary electrode 240s1 to the second electrode 220 through the coupling capacitor. That is, the second auxiliary electrode 240s1 may serve to supplement a signal transmitted from the second electrode 220 to the sensor driving unit 200C. Thus, the greatest effect may be obtained when a phase of a signal induced in the second auxiliary electrode 240s1 and a phase of a signal induced in the second electrode 220 coincide with each other. Thus, a center of each of the second electrodes 220 in the first direction DR1 and a center of each of the second auxiliary electrodes 240s1 in the first direction DR1 may overlap each other. Further, a center of each of the second electrodes 220 in the second direction DR2 and a center of each of the second auxiliary electrodes 240s1 in the second direction DR2 may also overlap each other.

Each of the first auxiliary electrodes 230s included in the third electrode 230 may include a (3-1)^{th} pattern 231 and a (3-2)^{th} pattern 232. The (3-1)^{th} pattern 231 and the (3-2)^{th} pattern 232 may be arranged on different layers, and the (3-1)^{th} pattern 231 and the (3-2)^{th} pattern 232 may be electrically connected to each other through a second contact CNb. The (3-1)^{th} pattern 231 may be included in the first conductive layer 202SU, and the (3-2)^{th} pattern 232 may be included in the second conductive layer 204SU.

In one or more embodiments of the present disclosure, a portion of the (3-1) th pattern 231 may overlap a portion of each of the first split electrodes 210dv1 and 210dv2. Thus, a coupling capacitance may be provided (or formed) between the first electrode 210 and the third electrode 230.

Each of the second auxiliary electrodes 240s1 or 240s2 included in the

fourth electrode 240 may include a (4-1)^{th} pattern 241, a (4-2)^{th} pattern 242, and a (4-3)^{th} pattern 243. The (4-2)^{th} pattern 242 and the (4-3)^{th} pattern 243 may be arranged on (e.g., at) the same layer, and the (4-1)^{th} pattern 241 may be disposed on a different layer from the (4-2)^{th} pattern 242 and the (4-3)^{th} pattern 243. The (4-1)^{th} pattern 241 and the (4-2)^{th} pattern 242 may be electrically connected to each other through a third contact CNc, and the (4-1)^{th} pattern 241 and the (4-3)^{th} pattern 243 may be electrically connected to each other through a fourth contact CNd. The (4-2)^{th} pattern 242 and the (4-3)^{th} pattern 243 may be included in the first conductive layer 202SU, and the (4-1)^{th} pattern 241 may be included in the second conductive layer 204SU.

In one or more embodiments of the present disclosure, a portion of the (4-2)^{th} pattern 242 may overlap the sensing pattern 221 of each of the second split electrodes 220dv1 and 220dv2. Thus, a coupling capacitor may be provided (or formed) between the second electrode 220 and the fourth electrode 240.

In one or more embodiments of the present disclosure, the first conductive layer 202SU may further include dummy patterns DMP. Each of the dummy patterns DMP may be electrically floating or electrically grounded. In one or more embodiments of the present disclosure, the dummy patterns DMP may be omitted.

The sensor layer 200 may further include a plurality of first trace lines 210t arranged in the peripheral area 200NA, a plurality of first pads PD1 connected to the first trace lines 210t in one-to-one correspondence, a plurality of second trace lines 220t, and a plurality of second pads PD2 connected to the second trace lines 220t in one-to-one correspondence.

The first trace lines 210t may be electrically connected to the first electrodes 210 in one-to-one correspondence. The two first split electrodes 210dv1 and 210dv2 included in the one first electrode 210 may be connected to one first trace line from among the first trace lines 210t. Each of the first trace lines 210t may include a plurality of branches for connection to the two first split electrodes 210dv1 and 210dv2. In one or more embodiments of the present disclosure, the two first split electrodes 210dv1 and 210dv2 may be connected to each other inside the active area 200A.

The second trace lines 220t may be electrically connected to the second electrodes 220 in one-to-one correspondence. The two second split electrodes 220dv1 and 220dv2 included in the one second electrode 220 may be connected to one second trace line from among the second trace lines 220t. Each of the second trace lines 220t may include a plurality of branches for connection to the two second split electrodes 220dv1 and 220dv2. In one or more embodiments of the present disclosure, the two second split electrodes 220dv1 and 220dv2 may be connected to each other inside the active area 200A.

The sensor layer 200 may further include a third trace line 230rt1 disposed in the peripheral area 200NA, a plurality of third pads PD3 connected to one end and the other end of the third trace line 230rt1, the fourth trace lines 240t-1 and 240t-2, fourth pads PD4 connected to the fourth trace lines 240t-1 and 240t-2 in one-to-one correspondence, fifth trace lines 230rt2, and fifth pads PD5 connected to the fifth trace lines 230rt2 in one-to-one correspondence.

The third trace line 230rt1 may be electrically connected to at least one first auxiliary electrode 230s from among the first auxiliary electrodes 230s. In one or more embodiments of the present disclosure, the third trace line 230rt1 may be electrically connected to all of the first auxiliary electrodes 230s. That is, the third trace line 230rt1 may be electrically connected to all of the third electrodes 230. The third trace line 230rt1 may include a first line portion 231t extending in the first direction DR1 and electrically connected to the third electrodes 230, a second line portion 232t extending from a first end of the first line portion 231t in the second direction DR2, and a third line portion 233t extending from a second end of the first line portion 231t in the second direction DR2.

In one or more embodiments of the present disclosure, each of a resistance of the second line portion 232t and a resistance of the third line portion 233t may be substantially the same as a resistance of the one third electrodes 230 from among the third electrodes 230. Thus, the second line portion 232t and the third line portion 233t may serve as the third electrodes 230, and the same effect may be obtained as if the third electrodes 230 are also arranged in the peripheral area 200NA. For example, any one of the second line portion 232t and the third line portion 233t and any one of the third electrodes 230 may form a coil. Thus, the pen positioned in an area adjacent to the peripheral area 200NA may also be sufficiently charged by a loop including the second line portion 232t or the third line portion 233t.

In one or more embodiments of the present disclosure, a width of each of the second line portion 232t and the third line portion 233t in the first direction DR1 may be adjusted to adjust the resistance of the second line portion 232t and the resistance of the third line portion 233t. However, this is merely an example, and the first to third line portions 231t, 232t, and 233t may have substantially the same width.

The fifth trace lines 230rt2 may be connected to the third electrodes 230 in one-to-one correspondence. That is, the number of fifth trace lines 230rt2 may correspond to the number of third electrodes 230. FIG. 7 illustrates three fifth trace lines 230rt2, as an example.

In one or more embodiments of the present disclosure, the fifth trace lines 230rt2 and the fifth pad PD5 may be omitted, and a charging drive mode for charging the pen may be omitted. In this case, the sensor layer 200 may sense an input by the active pen that may emit a magnetic field even when the magnetic field is not provided from the sensor layer 200.

The fourth trace lines 240t-1 and 240t-2 may be spaced (e.g., spaced apart) from each other with the active area 200A interposed therebetween. The fourth trace line 240t-1 may be electrically connected to at least one second auxiliary electrode 240s1 from among the second auxiliary electrodes 240s1. For example, one end of each of the second auxiliary electrodes 240s1 may be connected to the fourth trace line 240t-1. The fourth trace line 240t-2 may be electrically connected to at least one second auxiliary electrode 240s2 from among the second auxiliary electrodes 240s2. For example, one end of each of the second auxiliary electrodes 240s2 may be connected to the fourth trace line 240t-2.

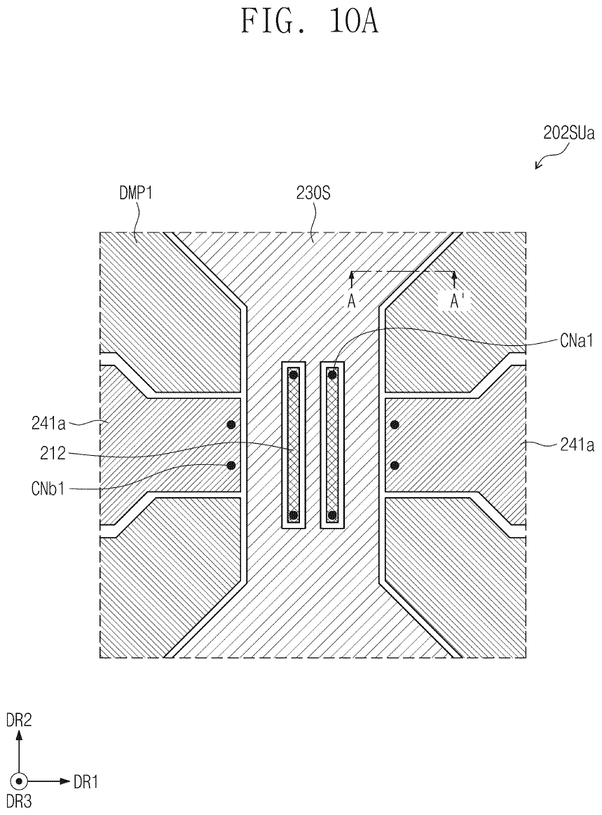

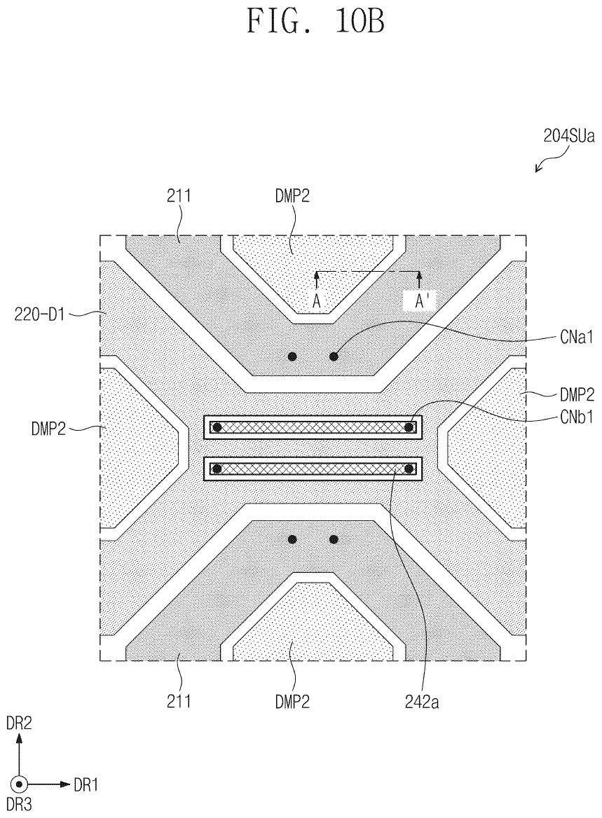

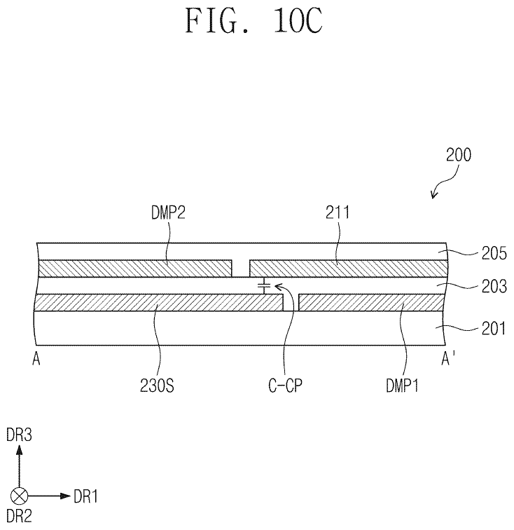

FIG. 10A is a plan view illustrating a first conductive layer of the sensing unit according to one or more embodiments of the present disclosure, FIG. 10B is a plan view illustrating a second conductive layer of the sensing unit according to one or more embodiments of the present disclosure, and FIG. 10C is a cross-sectional view of the sensor layer taken along the line A-A′ illustrated in FIGS. 10A and 10B according to one or more embodiments of the present disclosure.

Referring to FIGS. 8, 10A, 10B, and 10C, each of the first electrodes 210 may include a plurality of first sensing patterns 211 and a plurality of first bridge patterns 212. The first sensing patterns 211 may be spaced (e.g., spaced apart) from each other in the second direction DR2, and the first bridge patterns 212 may extend in the second direction DR2 and may be electrically connected to the first sensing patterns 211 through a first contact CNa1. FIGS. 10A and 10B illustrate as an example that two adjacent first sensing patterns 211 are electrically connected to each other through two first bridge patterns 212, but the present disclosure is not particularly limited thereto. For example, the two adjacent first sensing patterns 211 may be electrically connected to each other through one first bridge pattern 212 or electrically connected to each other through three or more first bridge patterns 212.

The first sensing patterns 211 adjacent to each other in the second direction DR2 may be spaced (e.g., spaced apart) from each other with the first split electrode 220-D1 interposed therebetween. In one or more embodiments of the present disclosure, the first sensing patterns 211 and the first split electrode 220-D1 may be included in a second conductive layer 204SUa, and the first bridge patterns 212 may be included in a first conductive layer 202SUa. The first bridge patterns 212 may be insulated from and intersect the first split electrode 220-D1 that overlaps the first bridge patterns 212.

Each of the first auxiliary electrodes 230s included in the plurality of third electrodes 230 may extend in the second direction DR2. The first auxiliary electrodes 230s may be included in the first conductive layer 202SUa. One or more holes may be defined in each of the first auxiliary electrodes 230s. The one first bridge pattern 212 may be disposed in one hole. Thus, the first bridge pattern 212 may be electrically insulated from the first auxiliary electrodes 230s.

Each of second auxiliary electrodes 240S included in the plurality of fourth electrodes 240 may include a plurality of second sensing patterns 241a and a plurality of second bridge patterns 242a. The second sensing patterns 241a may be spaced (e.g., spaced apart) from each other in the first direction DR1, and the second bridge patterns 242a may extend in the first direction DR1 and may be electrically connected to the second sensing patterns 241a through a second contact CNb1.

FIGS. 10A and 10B illustrate as an example that two adjacent second sensing patterns 241a are electrically connected to each other through two second bridge patterns 242a, but the present disclosure is not particularly limited thereto. For example, the two adjacent second sensing patterns 241a may be electrically connected to each other through one second bridge pattern 242a or electrically connected to each other through three or more second bridge patterns 242a.

In one or more embodiments of the present disclosure, the second sensing patterns 241a and the first auxiliary electrodes 230s may be included in the first conductive layer 202SUa, and the second bridge patterns 242a may be included in the second conductive layer 204SUa. The second bridge patterns 242a may be insulated from and intersect the first auxiliary electrodes 230s overlapping the second bridge patterns 242a.

Referring to FIGS. 10A and 10B, in the second conductive layer 204SU inside one sensing unit SU, an area occupied by components included in the plurality of first electrodes 210 and the plurality of second electrodes 220 may be greater than an area occupied by components included in the plurality of third electrodes 230 and the plurality of fourth electrodes 240. A change in the capacitance due to the first input 2000 (see FIG. 5) may be greater as a distance therefrom becomes shorter. Thus, components for sensing the first input 2000 (see FIG. 5) may be arranged in a relatively larger area in a layer adjacent to a surface of the electronic device 1000 (see FIG. 1). As a result, touch performance may be improved.

In one or more embodiments of the present disclosure, the first conductive layer 202SUa may further include first dummy patterns DMP1, and the second conductive layer 204SUa may further include second dummy patterns DMP2. Each of the first dummy patterns DMP1 and the second dummy patterns DMP2 may be floating or electrically floating. Each of the first dummy patterns DMP1 and the second dummy patterns DMP2 may be divided into a plurality of conductive patterns. For example, the one first dummy pattern DMP1 may include a plurality of floating dummy patterns that are separated or electrically separated from each other.

Referring to FIG. 10C, an area of the first auxiliary electrode 230s and an area of the first sensing pattern 211 may be adjusted. For example, a position of a boundary between the first auxiliary electrode 230s and the first dummy patterns DMP1 and a position of a boundary between the first sensing pattern 211 and the second dummy patterns DMP2 may be adjusted. In this case, an area of an overlapping area in which the first auxiliary electrode 230s and the first sensing pattern 211 overlap each other may be adjusted, and thus a magnitude of a capacitance of a coupling capacitor C-CP between the first auxiliary electrode 230s and the first sensing pattern 211 may be adjusted.

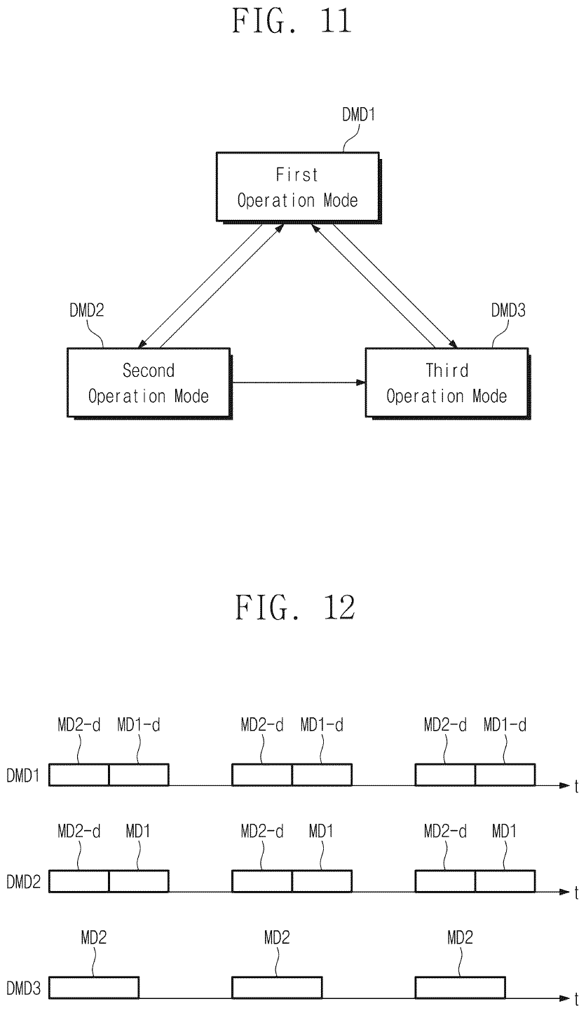

FIG. 11 is a view illustrating an operation of a sensor driving unit according to one or more embodiments of the present disclosure.

Referring to FIGS. 5 and 11, the sensor driving unit 200C may be configured to be selectively driven in one of a first operation mode DMD1, a second operation mode DMD2, and a third operation mode DMD3.

The first operation mode DMD1 may be referred to as a touch and pen waiting mode, the second operation mode DMD2 may be referred to as a touch activation and pen waiting mode, and the third operation mode DMD3 may be referred to as a pen activation mode. The first operation mode DMD1 may be a mode that waits for the first input 2000 and the second input 3000. The second operation mode DMD2 may be a mode that senses the first input 2000 and waits for the second input 3000. The third operation mode DMD3 may be a mode that senses the second input 3000.

In one or more embodiments of the present disclosure, the sensor driving unit 200C may be first driven in the first operation mode DMD1. When the first input 2000 is sensed in the first operation mode DMD1, the sensor driving unit 200C may be switched (or changed) to the second operation mode DMD2. Alternatively, when the second input 3000 is sensed in the first operation mode DMD1, the sensor driving unit 200C may be switched (or changed) to the third operation mode DMD3.

In one or more embodiments of the present disclosure, when the second input 3000 is sensed in the second operation mode DMD2, the sensor driving unit 200C may be switched to the third operation mode DMD3. When the first input 2000 is released (or not sensed) in the second operation mode DMD2, the sensor driving unit 200C may be switched to the first operation mode DMD1. When the second input 3000 is released (or not sensed) in the third operation mode DMD3, the sensor driving unit 200C may be switched to the first operation mode DMD1.

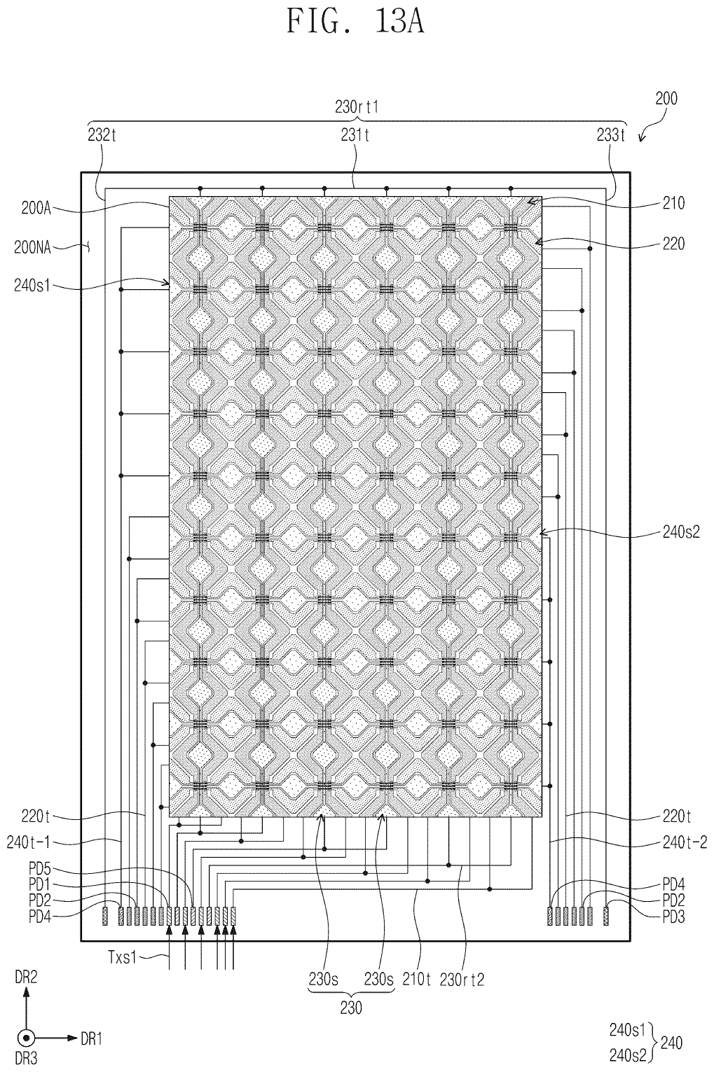

FIG. 12 is a view illustrating the operation of the sensor driving unit according to one or more embodiments of the present disclosure.

Referring to FIGS. 5, 7, 11, and 12, an operation in each of the first to third operation modes DMD1, DMD2, and DMD3 is illustrated in an order of a time “t”, as an example

In the first operation mode DMD1, the sensor driving unit 200C may be repeatedly driven in a second mode MD2-d and a first mode MD1-d. During the second mode MD2-d, the sensor layer 200 may be scan-driven to detect the second input 3000. During the first mode MD1-d, the sensor layer 200 may be scan-driven to detect the first input 2000. FIG. 12 illustrates as an example that the sensor driving unit 200C is operated in the first mode MD1-d continuously after the second mode MD2-d, but an order thereof is not limited thereto.

In the second operation mode DMD2, the sensor driving unit 200C may be repeatedly driven in the second mode MD2-d and a first mode MD1. During the second mode MD2-d, the sensor layer 200 may be scan-driven to detect the second input 3000. During the first mode MD1, the sensor layer 200 may be scan-driven to detect coordinates by the first input 2000.

In the third operation mode DMD3, the sensor driving unit 200C may be driven in a second mode MD2. During the second mode MD2, the sensor layer 200 may be scan-driven to detect coordinates by the second input 3000. In the third operation mode DMD3, the sensor driving unit 200C may not be operated in the first mode MD1-d or MD1 until the second input 3000 is released (or not sensed).

In the first mode MD1-d and the first mode MD1, all of the third electrodes 230 and the fourth electrodes 240 may be grounded. Thus, touch noise may be prevented from being introduced through the third electrodes 230 and the fourth electrodes 240.

In the second mode MD2-d and the second mode MD2, one end of each of the third electrodes 230 and the fourth electrodes 240 may be floating. Further, in the second mode MD2-d and the second mode MD2, the other end of each of the third electrodes 230 and the fourth electrodes 240 may be grounded or floating. Thus, compensation for the sensing signal may be maximized by coupling between the first electrodes 210 and the third electrodes 230 and coupling between the second electrodes 220 and the fourth electrodes 240.

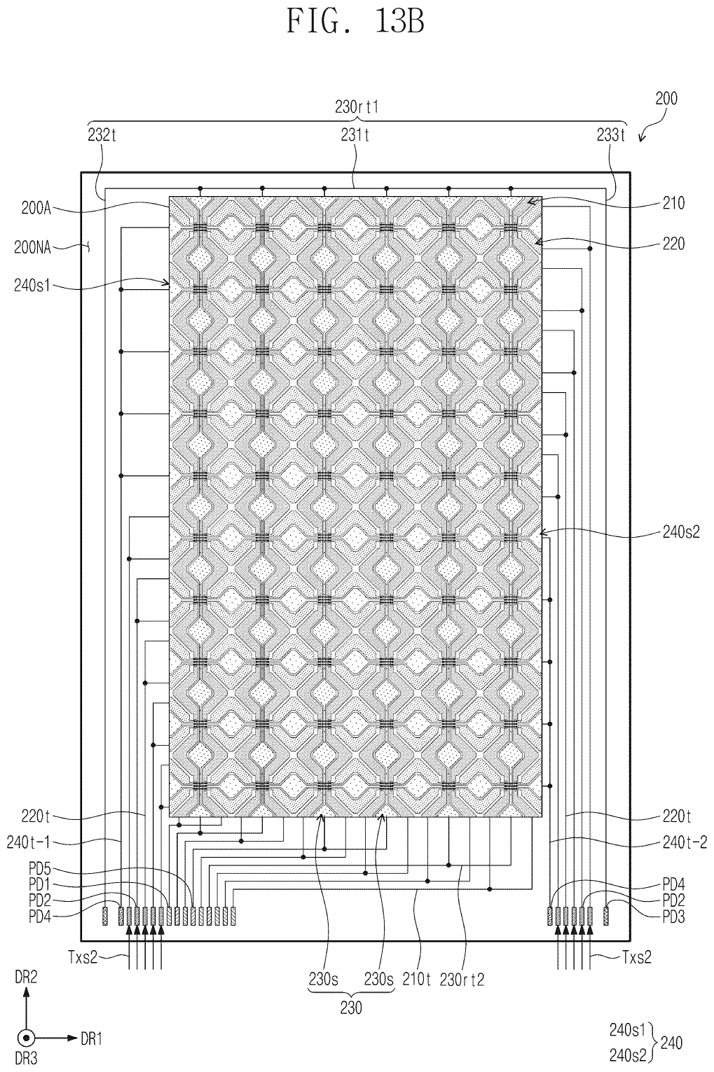

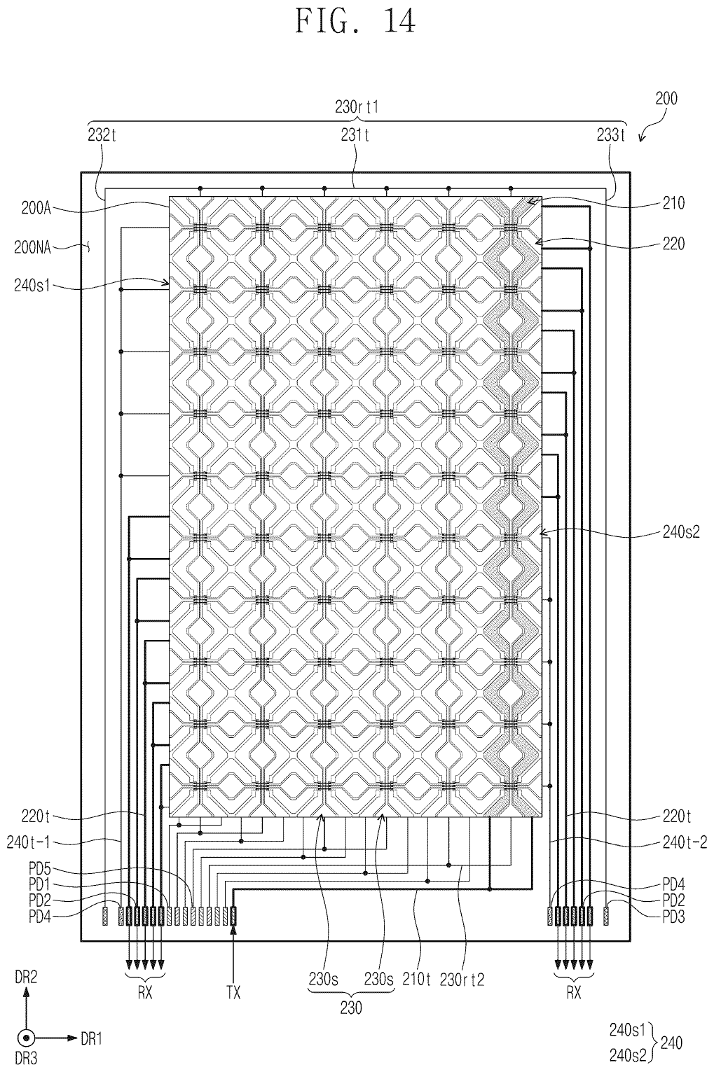

FIGS. 13A and 13B are views for describing a first mode according to one or more embodiments of the present disclosure.

Referring to FIGS. 12, 13A, and 13B, the first mode MD1-d and the first mode MD1 may include a self-capacitance detecting mode. The self-capacitance detecting mode may include a first sub-section and a second sub-section. FIG. 13A is a view for describing an operation in the first sub-section, and FIG. 13B is a view for describing an operation in the second sub-section.

In the self-capacitance detecting mode, the sensor driving unit 200C may output driving signals Txs1 and Txs2 to the first electrodes 210 and the second electrodes 220 and calculate input coordinates by sensing a change in the capacitance of each of the first electrodes 210 and the second electrodes 220. Referring to FIG. 13A, in the first sub-section, the sensor driving unit 200C may output the driving signal Txs1 to the first trace lines 210t. Referring to FIG. 13B, in the second sub-section, the sensor driving unit 200C may output the driving signal Txs2 to the second trace lines 220t.

The third electrodes 230 are electrically connected to the third trace line 230rt1 and the fifth trace line 230rt2, and the fourth electrodes 240 are electrically connected to the fourth trace lines 240t-1 and 240t-2. In the self-capacitance detecting mode, all of the third electrodes 230 and the fourth electrodes 240 may be grounded. Thus, noise may not be introduced through the third electrodes 230 and fourth electrodes 240.

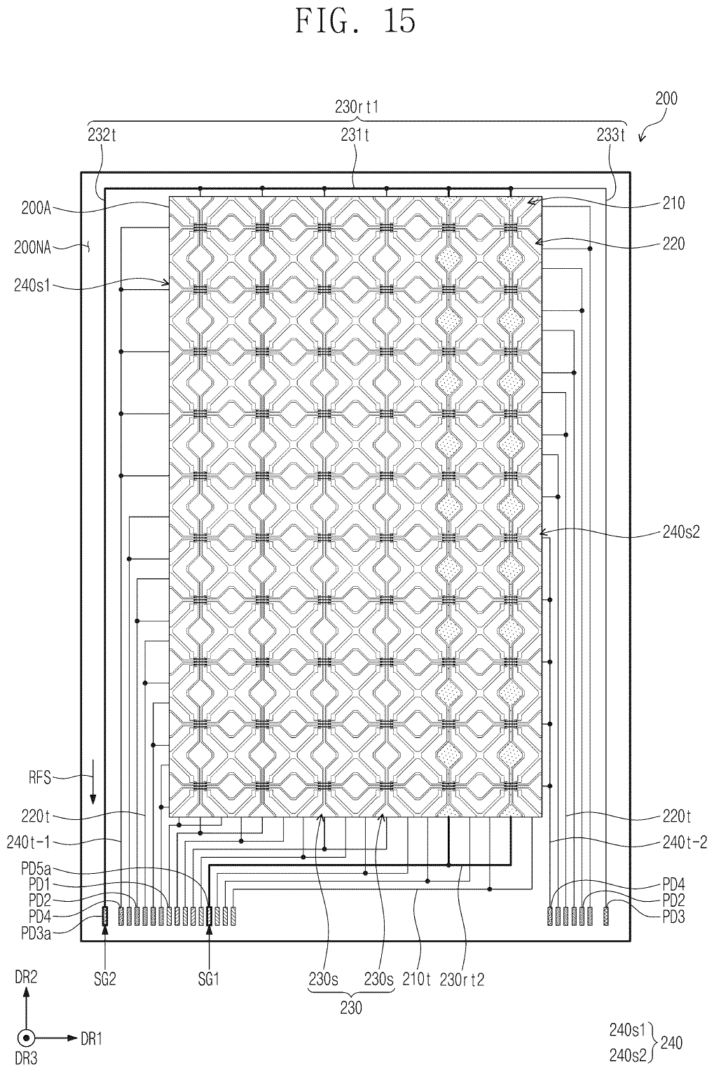

FIG. 14 is a view for describing the first mode according to one or more embodiments of the present disclosure.

Referring to FIGS. 5, 12, and 14, the first mode MD1-d and the first mode MD1 may further include a mutual capacitance detecting mode. FIG. 14 is a view for describing the mutual capacitance detecting mode in the first mode MD1-d and the first mode MD1.

In the mutual capacitance detecting mode, the sensor driving unit 200C may sequentially provide a transmission signal TX to the first electrodes 210 and detect coordinates for the first input 2000 using a reception signal RX detected through the second electrodes 220. For example, the sensor driving unit 200C may calculate input coordinates by sensing a change in the mutual capacitance between the first electrodes 210 and the second electrodes 220.

FIG. 14 illustratively expresses that the transmission signal TX is provided to the one first electrode 210 and the reception signal RX is output from the second electrodes 220. To clarify the expression of the signal, in FIG. 14, only the one first electrode 210 to which the transmission signal TX is provided is hatched. The sensor driving unit 200C may detect input coordinates for the first input 2000 by sensing a change in the capacitance between the first electrodes 210 and the second electrodes 220.

In the mutual capacitance detecting mode, all of the third electrodes 230 and the fourth electrodes 240 may be grounded. Thus, noise may not be introduced through the third electrodes 230 and fourth electrodes 240.

In each of the first mode MD1-d and the first mode MD1, the sensor layer 200 may alternately and repeatedly perform the operations described in FIGS. 13A, 13B, and 14. However, this is merely an example, and the present disclosure is not particularly limited thereto. For example, in each of the first mode MD1-d and the first mode MD1, the sensor layer 200 may repeatedly perform only the operation described in FIG. 14. Alternatively, in the first mode MD1-d, the sensor layer 200 may repeatedly perform only at least one operation from among the operations described in FIGS. 13A, 13B, and 14, and in the first mode MD1, the sensor layer 200 may alternately and repeatedly perform the operations described in FIGS. 13A, 13B, and 14.

FIG. 15 is a view for describing a second mode according to one or more embodiments of the present disclosure.

Referring to FIGS. 5, 12, and 15, the second mode MD2 may include a charging drive mode and a pen sensing drive mode.

In the charging drive mode, the sensor driving unit 200C may apply a first charging signal SG1 to one pad from among the third pads PD3 and the fifth pads PD5 and apply a second charging signal SG2 to at least the other one pad. The second charging signal SG2 may be an inverse phase signal of the first charging signal SG1. For example, the first charging signal SG1 may be a sinusoidal or square wave signal.

FIG. 15 illustrates as an example that the first charging signal SG1 is applied to one pad, and the second charging signal SG2 is applied to the other one pad, but the present disclosure is not limited thereto. For example, the first charging signal SG1 may be applied to two or more pads, and the second charging signal SG2 may be applied to two or more other pads.

Because the first charging signal SG1 and the second charging signal SG2 are applied to at least two pads, a current RFS may have a current path flowing through at least one pad to at least one other pad. Further, because the first charging signal SG1 and the second charging signal SG2 are sinusoidal signals having an inverse phase relationship, a direction of the current RFS may be changed periodically.

The first charging signal SG1 and the second charging signal SG2 may have an inverse phase relationship. Thus, noise caused in the display layer 100 by the first charging signal SG1 and noise caused by the second charging signal SG2 may be canceled out from each other. Thus, a flicker phenomenon may not occur in the display layer 100, and display quality of the display layer 100 may be improved.

It is illustrated that the second charging signal SG2 is provided to one third pad PD3a connected to the one third trace line 230rt1, and the first charging signal SG1 is provided to one fifth pad PD5a connected to the third electrode 230. The current RFS may flow through a current path defined by the fifth pad PD5a, the fifth trace line 230rt2 connected to the fifth pad PD5a, the third electrode 230, a portion of the third trace line 230rt1 connected to the third pad PD3a, and the third pad PD3a.

The current path may have a coil shape. Thus, in the charging drive mode of the second mode, a resonant circuit of the pen PN may be charged by the current path. In this case, the plurality of third electrodes 230 may be referred to as a plurality of channels.

According to the present disclosure, the current path having a loop coil pattern may be implemented by components included in the sensor layer 200. Thus, the electronic device 1000 may charge the pen PN using the sensor layer 200. Thus, because an additional component having a coil for charging the pen PN is not separately required, an increase in the thickness, an increase in the weight, and a decrease in the flexibility of the electronic device 1000 may not occur.

In the charging drive mode, the first electrodes 210, the second electrodes 220, and the fourth electrodes 240 may be grounded or electrically floating, or a constant voltage may be applied thereto. In particular, the first electrodes 210, the second electrodes 220, and the fourth electrodes 240 may be floating. In this case, the current RFS may not flow through the first electrodes 210, the second electrodes 220, and the fourth electrodes 240.

The charging drive mode may include a searching charging drive mode and a tracking charging drive mode.

In the searching charging drive mode, because a position of the pen PN is not sensed, the first charging signal SG1 or the second charging signal SG2 may be sequentially provided to all of channels included in the sensor layer 200. For example, the first charging signal SG1 and the second charging signal SG2 may be sequentially scanned in the first direction DR1. That is, in the searching charging drive mode, the entire active area 200A of the sensor layer 200 may be scanned.

In the searching charging drive mode, when the pen PN is sensed, the sensor layer 200 may be driven for tracking charging. For example, in the tracking charging drive mode, the sensor driving unit 200C may sequentially output the first charging signal SG1 and the second charging signal SG2 to an area overlapping a point at which the pen PN is sensed rather than the entire sensor layer 200.

Thus, after the position of the pen PN is sensed, channels that are charged and driven to correspond to the position of the pen PN of an immediately previous frame may be limited. Thus, efficiency of charging drive may be improved as channels overlapping an area in which the pen PN is not positioned are not charged and driven.

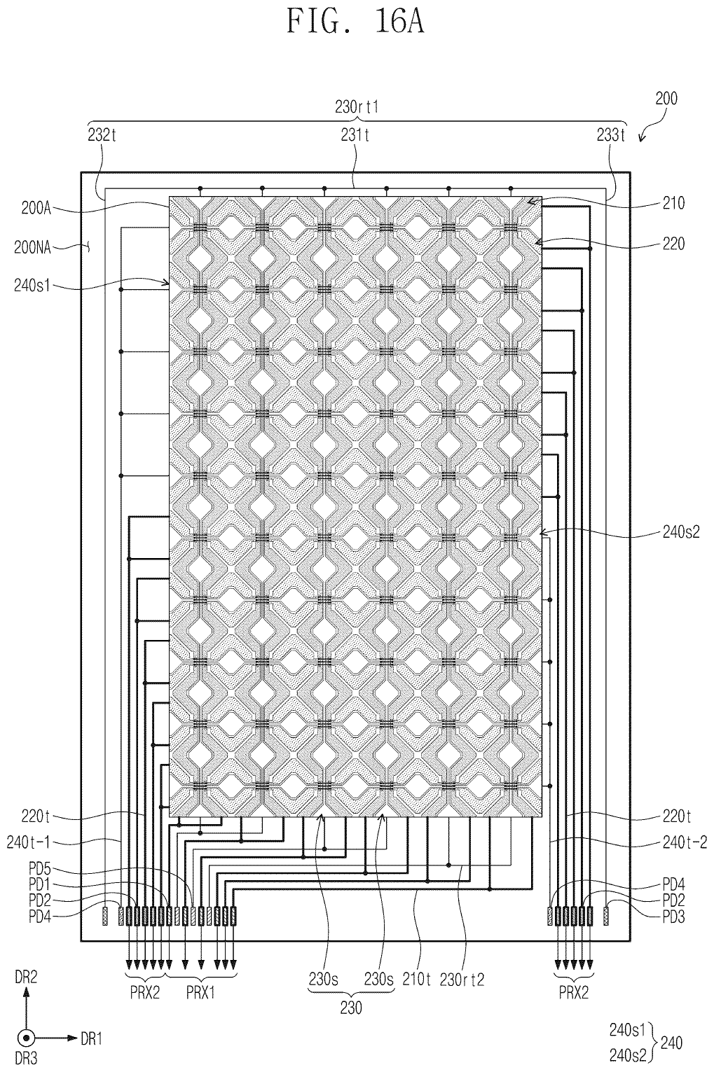

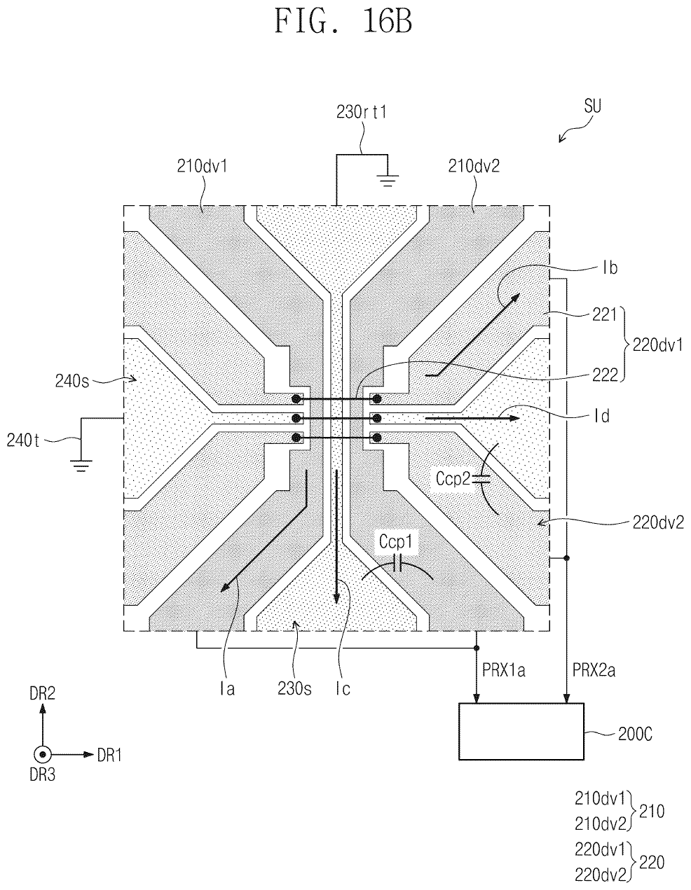

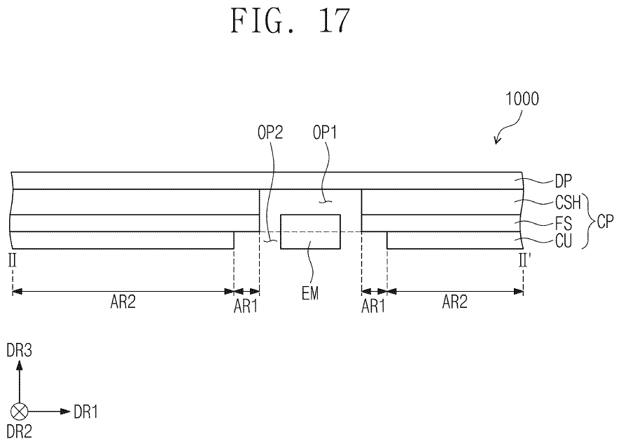

FIG. 16A is a view for describing the second mode according to one or more embodiments of the present disclosure, and FIG. 16B is a view for describing the second mode based on sensing units according to one or more embodiments of the present disclosure.

Referring to FIGS. 5, 16A, and 16B, in the second mode, the charging drive mode and the pen sensing drive mode may be alternately and repeatedly performed. FIG. 16B illustrates the one sensing unit SU through which first to fourth induced currents Ia, Ib, Ic, and Id generated by the pen PN flow.

The RLC resonant circuit of the pen PN may emit a magnetic field having a resonant frequency while discharging the charged charges. By the magnetic field provided in the pen PN, the first induced current Ia may be generated in the first electrode 210, and the second induced current Ib may be generated in the second electrode 220. Further, the third induced current Ic may be generated in the first auxiliary electrode 230s of the third electrode 230, and the fourth induced current Id may also be generated in the second auxiliary electrode 240s of the fourth electrode 240.

A first coupling capacitor Ccp1 may be formed between the first auxiliary electrode 230s and the first electrode 210, and a second coupling capacitor Ccp2 may be formed between the second auxiliary electrode 240s and the second electrode 220. The third induced current Ic may be transmitted to the first electrode 210 through the first coupling capacitor Ccp1, and the fourth induced current Id may be transmitted to the second electrode 220 through the second coupling capacitor Ccp2. In this case, each of the plurality of first electrodes 210 and the plurality of second electrodes 220 may be referred to as a channel.

The sensor driving unit 200C may receive, from the first electrode 210, a first sensing signal PRX1a based on the first induced current Ia and the third induced current Ic and may receive, form the second electrode 220, a second sensing signal PRX2a based on the second induced current Ib and the fourth induced current Id. That is, the sensor driving unit 200C may receive a first sensing signal PRX1a from the plurality of first electrodes 210 and receive a second sensing signal PRX2a from the plurality of second electrodes 220. The sensor driving unit 200C may detect coordinates of the pen PN based on the first sensing signal PRX1a and/or the second sensing signal PRX2a.

The sensor driving unit 200C may receive the first sensing signal PRX1a from the first electrodes 210 and receive the second sensing signal PRX2a from the second electrodes 220. In this case, both ends of the third electrodes 230 and the fourth electrodes 240 may be floating. Thus, the compensation for the sensing signal may be maximized by the coupling between the first electrodes 210 and the third electrodes 230 and the coupling between the second electrodes 220 and the fourth electrodes 240. Further, the other ends of the third electrodes 230 and the fourth electrode 240 may be grounded or floating. Thus, the third induced current Ic may be sufficiently transmitted to the first electrodes 210 by the coupling between the first electrodes 210 and the third electrodes 230, and the fourth induced current Id may be sufficiently transmitted to the second electrodes 220 by the coupling between the second electrodes 220 and the fourth electrodes 240.

In one or more embodiments of the present disclosure, routing directions of an electrode and an auxiliary electrode of the sensor layer 200, which overlap each other, may be different from each other. For example, the routing direction of the first electrode 210 and the routing direction of the first auxiliary electrode 230s may be different from each other. Further, the routing direction of the second electrode 220 and the routing direction of the second auxiliary electrode 240s may be different from each other. For example, in FIGS. 16A-16B, the first electrode 210 and the first trace line 210t may be connected to each other at a lower portion of the sensing unit SU, and the first auxiliary electrode 230s and the third trace line 230rt1 may be connected to each other at an upper portion of the sensing unit SU. The second electrode 220 and the second trace line 220t may be connected to each other at a left portion of the sensing unit SU, and the second auxiliary electrode 240s and the fourth trace line 240t may be connected to each other at a right portion of the sensing unit SU.

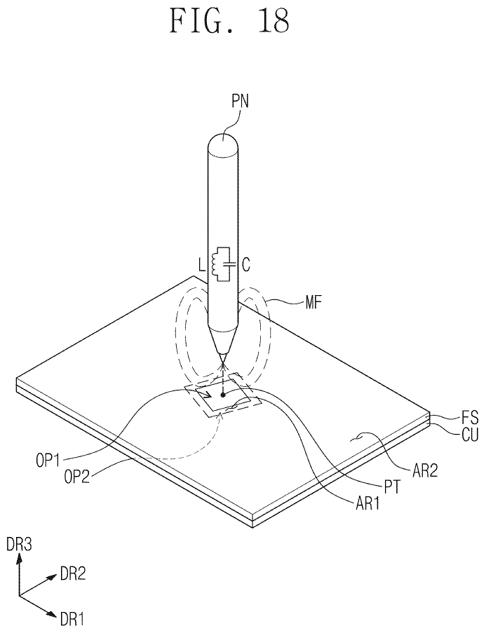

FIG. 17 is a cross-sectional view of the electronic device taken along the line II-II′ of FIG. 2 according to one or more embodiments of the present disclosure.

Referring to FIG. 17, the electronic device 1000 may include the display panel DP, the cover panel CP, and an electronic module EM.

The electronic module EM and the cover panel CP may be arranged under the display panel DP.

The cover panel CP may include the cushion layer CSH, the magnetic layer FS, and the conductive layer CU.

The cushion layer CSH may be disposed under the display panel DP. The cushion layer CSH may include a cushion sheet and an embossed sheet.

The embossed sheet may be colored. For example, the embossed sheet may be black. The embossed sheet may absorb a light input into the cushion layer CSH.

The cushion sheet may alleviate a pressure applied from the outside. The cushion sheet may include a sponge, foam, urethane resin, and/or the like. A thickness of the cushion sheet may be greater than a thickness of the embossed sheet.

When the cushion layer CSH is attached, the embossed sheet may include an embo pattern to prevent bubbles from being generated.

The cushion sheet may protect the display panel DP from an impact transmitted from the lower side. Impact resistance characteristics of the electronic device 1000 may be improved by the cushion layer CSH.

The magnetic layer FS may be disposed under the cushion layer CSH. The magnetic layer FS may reflect a magnetic field passing through the display panel DP. Therefore, the magnetic field reaching the magnetic layer FS may be reflected upward. For example, the magnetic layer FS may serve to guide a direction of the passing magnetic field to a different direction. Thus, the magnetic field that reaches the magnetic layer FS may be shielded without leaking to the outside, for example, to a lower portion of the magnetic layer FS. Thus, the magnetic layer FS may prevent signal interference from the outside.

The magnetic layer FS may include a magnetic material containing an iron oxide such as magnetic metal powder and ferrite. The magnetic layer FS may be referred to as a ferrite sheet, a magnetic metal powder layer, a magnetic layer, a magnetic circuit layer, and/or a magnetic path layer.

The conductive layer CU may be disposed under the magnetic layer FS. The conductive layer CU may be conductive. The conductive layer CU may shield the magnetic field passing through the magnetic layer FS to prevent the magnetic field from leaking to the outside, for example, to a lower portion of the conductive layer CU.

Further, the conductive layer CU may block a magnetic field generated from a component (e.g., an antenna) disposed under the conductive layer CU to prevent the magnetic field from reaching the display panel.

The conductive layer CU may include aluminum, copper, and/or a copper alloy. For example, the conductive layer CU may be a copper tape. However, the present disclosure is not limited thereto.

A ground voltage may be applied to the conductive layer CU. However, this is illustrative, and the conductive layer CU may be floating.

According to the present disclosure, the magnetic layer FS and the conductive layer CU may be laminated such that the magnetic layer FS is closer to the display panel DP than the conductive layer CU. A magnetic field generated by the pen PN (see FIG. 5) may be sensed through the sensor layer 200 (see FIG. 5), and in this case, the magnetic field may be reflected by the magnetic layer FS, and thus, sensing reliability of the sensor layer 200 (see FIG. 5) may be improved. The magnetic field passing through the magnetic layer FS may be blocked by the conductive layer CU.

The conductive layer CU may improve signal reliability by blocking a magnetic field generated on an upper side of the conductive layer CU and a magnetic field generated on a lower side of the conductive layer CU. Thus, the electronic device 1000 having improved reliability may be provided.

A first opening OP1 may be defined in the cushion layer CSH and the magnetic layer FS.

A second opening OP2 may be defined in the conductive layer CU.

A first area of the first opening OP1 may be smaller than a second area of the second opening OP2. The first opening OP1 may correspond to the sensing area SA (see FIG. 2).

The electronic module EM may be disposed inside the first opening OP1 and the second opening OP2. The electronic module EM may include the fingerprint sensor 1610 (see FIG. 1). However, this is illustrative, and the electronic module EM according to one or more embodiments of the present disclosure may include the sound output module 1630 (see FIG. 1). In this case, the sound output module 1630 (see FIG. 1) may include a piezo type speaker. Alternatively, the electronic module EM may include a photo sensor.

Unlike the present disclosure, when the fingerprint sensor 1610 is in contact with the magnetic layer FS, reliability of the fingerprint sensor 1610 may be decreased. However, according to the present disclosure, when viewed on a plane (e.g., in a plan view), the electronic module EM may not overlap the magnetic layer FS and the conductive layer CU. The electronic module EM may be spaced (e.g., spaced apart) from the magnetic layer FS and the conductive layer CU. Reliability of the electronic module EM may be improved. Thus, the electronic device 1000 having improved reliability may be provided.

A first area AR1 and a second area AR2 may be defined in the cover panel CP.

The first area AR1 may be adjacent to the electronic module EM. When viewed on a plane, the first area AR1 may surround the electronic module EM.

The second area AR2 may cover the first area AR1. When viewed on a plane, the second area AR2 may be around (e.g., may surround) the first area AR1. The second area AR2 may be spaced (e.g., spaced apart) from the first opening OP1 with the first area AR1 interposed therebetween. When viewed on a plane, an area of the second opening OP2 may be a value obtained by adding an area of the first area AR1 to an area of the first opening OP1.

When viewed on a plane, the first area AR1 may be defined between the second area AR2 and the first opening OP1. When viewed on a plane, at least a portion of the second opening OP2 may overlap the first area AR1.

When viewed on a plane, the conductive layer CU may overlap only the second area AR2. The conductive layer CU may not overlap the first area AR1. The cushion layer CSH and the magnetic layer FS may overlap the first area AR1 and the second area AR2. Therefore, the first area AR1 and the second area AR2 of the cover panel CP may have different magnetic permeability.

The first area AR1 of the cover panel CP may have a first magnetic permeability. The second area AR2 of the cover panel CP may have a second magnetic permeability that is different from the first magnetic permeability.

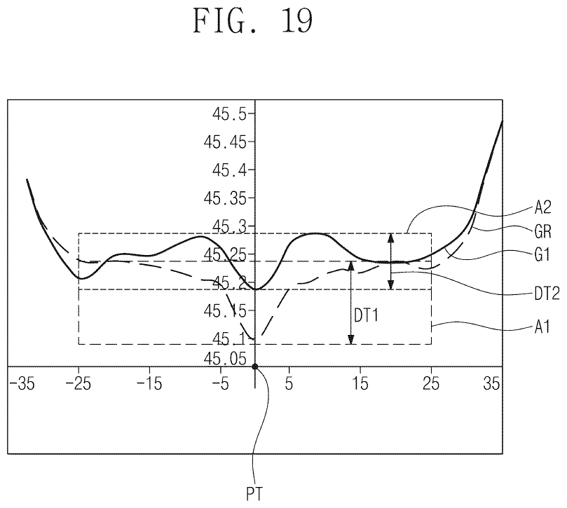

FIG. 18 is a perspective view illustrating a portion of a cover panel and a pen according to one or more embodiments of the present disclosure, and FIG. 19 is a graph depicting an inductance for each position according to one or more embodiments of the present disclosure.

Referring to FIGS. 5, 18, and 19, when viewed on a plane, the magnetic layer FS may cover the conductive layer CU. Magnetic permeability of the magnetic layer FS may be higher than magnetic permeability of the conductive layer CU.

The pen PN may be disposed on the magnetic layer FS and the conductive layer CU. FIG. 18 illustrates, as an example, that the pen PN is disposed at a point PT that is a center of the first opening OP1.

The pen PN may include an inductor “L” and a capacitor “C.” The inductor “L” may emit a magnetic field MF having a resonant frequency. An induced current may flow in the sensor layer 200 by the magnetic field MF emitted by the pen PN, and the induced current as a reception signal (or a sensing signal) may be transmitted to the sensor driving unit 200C.

A reference graph GR illustrates an inductance measured when the pen PN is moved in the first direction DR1 in a comparative example in which the first area AR1 and the second area AR2 have the same magnetic permeability. For example, in the comparative example, when viewed on a plane, the first opening OP1 and the second opening OP2 may have the same area.

When viewed on a plane, the second opening OP2 having a larger area than that of the first opening OP1 of the magnetic layer FS may be defined in the conductive layer CU. The magnetic layer FS may overlap the first area AR1 and the second area AR2, and the conductive layer CU may not overlap the first area AR1 due to the second opening OP2. Therefore, the first magnetic permeability of the first area AR1 may be different from the second magnetic permeability of the second area AR2.

A first graph G1 illustrates an inductance measured when the pen PN is moved in the first direction DR1 in an embodiment of the present disclosure in which the first area AR1 and the second area AR2 have different magnetic permeability.

An x axis in each of the reference graph GR and the first graph G1 may refer to a position of the pen PN. For example, the x axis represents −35 mm to 35 mm in 5 mm increments with the point PT, which is the center of the first opening OP1, set as 0 mm. For example, a range from −4 mm to 4 mm may correspond to the first opening OP1, ranges from −6 mm to −4 mm and 4 mm to 6 mm may correspond to the first area AR1, and ranges from −25 mm to −6 mm and 6 mm to 25 mm may correspond to the second area AR2.

An y axis in each of the reference graph GR and the first graph G1 may refer to an inductance. For example, the y axis represents 45.05 H (Henry) to 45.5 H in 0.05H increments.

The second opening OP2 may be defined in the conductive layer CU according to one or more embodiments of the present disclosure, and thus the conductive layer CU may not overlap the first area AR1. An eddy current formed by the magnetic field MF may not be blocked by the conductive layer CU in the first area AR1. The first magnetic permeability of the first area AR1 may be higher than the second magnetic permeability of the second area AR2.

The inductance may be proportional to the magnetic permeability. The inductance of a portion adjacent to the first area AR1 and the inductance of a portion adjacent to the first opening OP1 may be increased.

Unlike the present disclosure, referring to the reference graph GR, an inductance change amount DT1 according to the comparative example may be relatively large in a measurement area A1 according to the comparative example. In this case, when the sensor driving unit 200C senses coordinates of the pen PN, the sensor driving unit 200C may deviate from a possible correction range, the reception signal may not be corrected, and thus, the sensing reliability may be degraded.

However, according to the present disclosure, referring to the first graph G1 measured based on the electronic device 1000, an inductance change amount DT2 in a measurement area A2 may be relatively small. That is, the inductance change amount DT2 according to one or more embodiments of the present disclosure may be decreased as compared to the inductance change amount DT1 according to the comparative example. The reception signal may have a value within a correction range of the sensor driving unit 200C. Thus, the sensor driving unit 200C may correct the reception signal, and thus sensing reliability may be improved.

According to the present disclosure, in the sensing area SA (see FIG. 2) in which the electronic module EM is disposed, the magnetic layer FS and the conductive layer CU may not overlap the electronic module EM. The magnetic permeability of the first area AR1 adjacent to the sensing area SA (see FIG. 2) may be higher than the magnetic permeability of the second area AR2. Therefore, the inductance change amount DT2 of the magnetic field MF in the sensing area SA (see FIG. 2) and an area adjacent to the sensing area SA (see FIG. 2) may be decreased. Therefore, sensing reliability in one area of the sensor layer 200, which overlaps the sensing area SA, may be improved. Linearity of the input by the pen PN may be improved. Thus, the electronic device 1000 having improved sensing reliability may be provided.

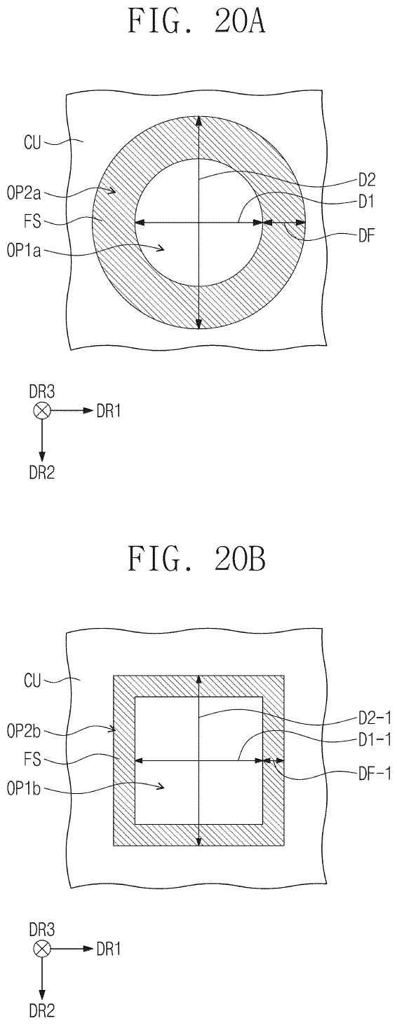

FIG. 20A is a plan view illustrating a portion of a rear surface of the cover panel according to one or more embodiments of the present disclosure.

Referring to FIGS. 17 and 20A, each of a first opening OP1a and a second opening OP2a may have a circular shape.

The first opening OP1a may have a first diameter D1. For example, the first diameter D1 may be 8 mm.

A difference DF between a radius of the first opening OP1a and a radius of the second opening OP2a may be 2 mm.

The second opening OP2a may have a second diameter D2. For example, the second diameter D2 may be 12 mm.

A second area of the second opening OP2a may be 1.5 to 1.6 times a first area of the first opening OP1a. The magnetic permeability of the first area AR1 may be defined by the first area and the second area.

Unlike the present disclosure, when the second area is smaller than 1.5 times the first area, an inductance of a portion adjacent to the first area AR1 and an inductance of a portion adjacent to the first opening OP1a may be less increased, and when the second area is greater than 1.6 times the first area, the inductance of the portion adjacent to the first area AR1 and the inductance of the portion adjacent to the first opening OP1a may be excessively increased, and thus the amount of change in the inductance may be increased. However, according to the present disclosure, the amount of increase in the inductance may be controlled by a relationship between the second area of the second opening OP2a and the first area of the first opening OP1a. The amount of change in the inductance may be relatively small due to an increase in inductance in the first opening OP1a, the first area AR1, and second area AR2. The reception signal may have the value within the correction range of the sensor driving unit 200C (see FIG. 5). Thus, the sensor driving unit 200C (see FIG. 5) may correct the reception signal, and thus the sensing reliability may be improved.

FIG. 20B is a plan view illustrating the portion of the rear surface of the cover panel according to one or more embodiments of the present disclosure.

Referring to FIGS. 17 and 20B, each of a first opening OP1b and a second opening OP2b may have a quadrangle shape. For example, each of the first opening

OP1b and the second opening OP2b may have a square shape. However, this is illustrative, and the shape of each of the first opening OP1b and the second opening OP2b is not limited thereto. For example, the shape of each of the first opening OP1b and the second opening OP2b may be a polygonal shape such as a triangular shape or an octagonal shape.

The first opening OP1b may have a first width D1-1 in the first direction DR1. For example, the first width D1-1 may be 8 mm.

A width DF-1 between the first opening OP1b and the second opening OP2b may be 2 mm.

The second opening OP2b may have a second width D2-1 in the second direction DR2. For example, the second width D2-1 may be 12 mm.

A second area of the second opening OP2b may be 1.5 to 1.6 times a first area of the first opening OP1b. The magnetic permeability of the first area AR1 may be defined by the first area and the second area.

Unlike the present disclosure, when the second area is smaller than 1.5 times the first area, the inductance of the portion adjacent to the first area AR1 and the inductance of the portion adjacent to the first opening OP1b may be less increased, and when the second area is greater than 1.6 times the first area, the inductance of the portion adjacent to the first area AR1 and the inductance of the portion adjacent to the first opening OP1b may be excessively increased, and thus the amount of change in the inductance may be increased. However, according to the present disclosure, the amount of increase in the inductance may be controlled by a relationship between the second area of the second opening OP2b and the first area of the first opening OP1b. The amount of change in the inductance may be relatively small due to the increase in the inductance in the first opening OP1a, the first area AR1, and second area AR2. The reception signal may have the value within the correction range of the sensor driving unit 200C (see FIG. 5). Thus, the sensor driving unit 200C (see FIG. 5) may correct the reception signal, and thus the sensing reliability may be improved.

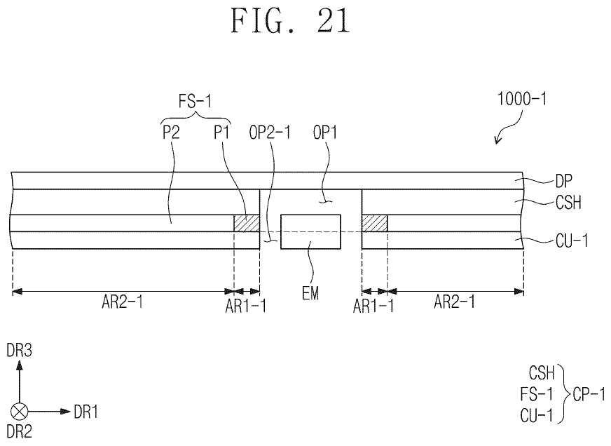

FIG. 21 is a cross-sectional view of the electronic device taken along the line corresponding to the line II-II′ of FIG. 2 according to one or more embodiments of the present disclosure. In the description of FIG. 21, the components described through FIG. 17 are designated by the same reference numerals, and a description thereof will be omitted.

Referring to FIG. 21, an electronic device 1000-1 may include the display panel DP, a cover panel CP-1, and the electronic module EM.

The electronic module EM and the cover panel CP-1 may be arranged under the display panel DP.

The cover panel CP-1 may include the cushion layer CSH, a magnetic layer FS-1, and a conductive layer CU-1. A first area AR1-1 and a second area AR2-1 may be defined in the cover panel CP-1.

The first area AR1-1 may be adjacent to the electronic module EM. When viewed on a plane, the first area AR1-1 may be around (e.g., may surround) the electronic module EM.

The second area AR2-1 may cover the first area AR1-1. The second area AR2-1 may be around (e.g., may surround) the first area AR1-1. The second area AR2-1 may be spaced (e.g., spaced apart) from the first opening OP1 with the first area AR1-1 interposed therebetween.

When viewed on a plane, the first area AR1-1 may be defined between the second area AR2-1 and the first opening OP1.

The magnetic layer FS-1 may include a first portion P1 disposed in the first area AR1-1 and a second portion P2 disposed in the second area AR2-1.

The magnetic permeability of the first portion P1 may be higher than the magnetic permeability of the second portion P2.

The first opening OP1 may be defined in the cushion layer CSH and the magnetic layer FS-1.

A second opening OP2-1 may be defined in the conductive layer CU-1.

The first area of the first opening OP1 may be the same as the second area of the second opening OP2-1

When viewed on a plane, the magnetic layer FS-1 and the conductive layer CU-1 may overlap the first area AR1-1 and the second area AR2-1.

The first area AR1-1 of the cover panel CP-1 may have a first magnetic permeability. The second area AR2-1 of the cover panel CP-1 may have a second magnetic permeability that is smaller than the first magnetic permeability.

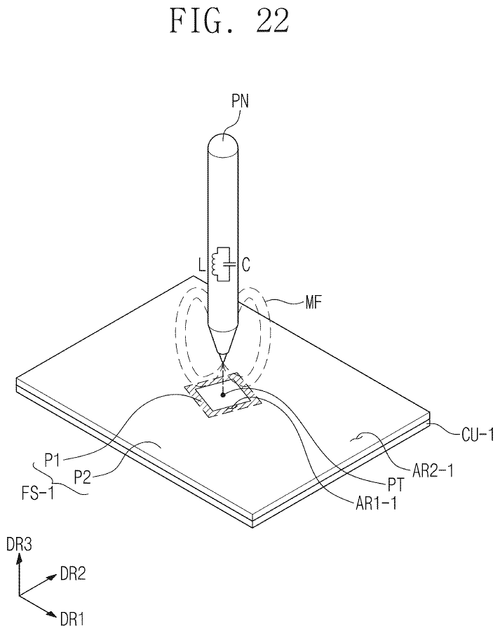

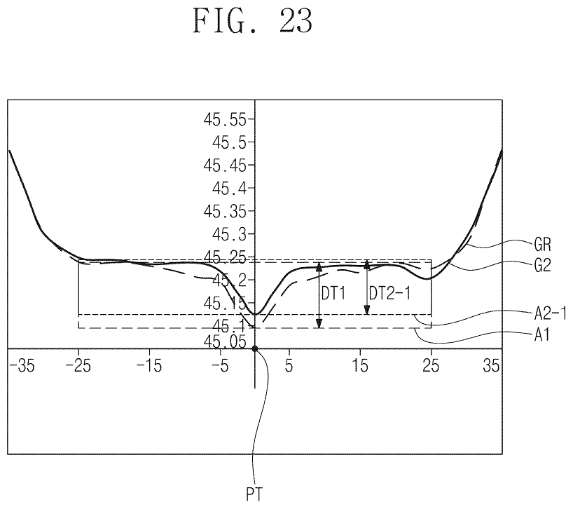

FIG. 22 is a perspective view illustrating the portion of the cover panel and the pen according to one or more embodiments of the present disclosure, and FIG. 23 is a graph depicting an inductance for each position according to one or more embodiments of the present disclosure. In the description of FIGS. 22 and 23, the components described through FIGS. 18 and 19 are designated by the same reference numerals, and a description thereof will be omitted.

Referring to FIGS. 5, 22, and 23, when viewed on a plane, the magnetic layer FS-1 may cover the conductive layer CU-1. The first magnetic permeability of the first area AR1-1 may be higher than the second magnetic permeability of the second area AR2-1.

The pen PN may be disposed on the magnetic layer FS-1 and the conductive layer CU-1. FIG. 22 illustratively illustrates that the pen PN is disposed at the point PT that is the center of the first opening OP1.

The pen PN may include the inductor “L” and the capacitor “C.” The inductor “L” may emit the magnetic field MF having the resonant frequency. The induced current may flow in the sensor layer 200 by the magnetic field MF emitted by the pen PN, and the induced current as the reception signal (or the sensing signal) may be transmitted to the sensor driving unit 200C.

A reference graph GR illustrates the inductance measured when the pen PN is moved in the first direction DR1 in a comparative example in which the first area AR1-1 and the second area AR2-1 have the same magnetic permeability.

A second graph G2 illustrates an inductance measured when the pen PN is moved in the first direction DR1 in one or more embodiments of the present disclosure in which the first area AR1-1 and the second area AR2-1 have different magnetic permeability.

The first magnetic permeability of the first area AR1-1 may be higher than the second magnetic permeability of the second area AR2-1. The inductance may be proportional to the magnetic permeability. The inductance of a portion adjacent to the first area AR1-1 and the inductance of a portion adjacent to the first opening OP1 may be increased.

Unlike the present disclosure, referring to the reference graph GR, the inductance change amount DT1 according to the comparative example may be relatively large in the measurement area A1 according to the comparative example. In this case, when the sensor driving unit 200C senses the coordinates of the pen PN, the sensor driving unit 200C may deviate from a possible correction range, the reception signal may not be corrected, and thus, the sensing reliability may be degraded. However, according to the present disclosure, referring to the second graph G2 measured based on the electronic device 1000, an inductance change amount DT2-1 in a measurement area A2-1 may be relatively small. That is, the inductance change amount DT2-1 according to one or more embodiments of the present disclosure may be decreased as compared to the inductance change amount DT1 according to the comparative example. The reception signal may have the value within the correction range of the sensor driving unit 200C. Thus, the sensor driving unit 200C may correct the reception signal, and thus the sensing reliability may be improved.

An area of the first portion P1 may be 0.2 to 0.3 times an area of each of the first opening OP1 and the second opening OP2-1.

Unlike the present disclosure, when the area of the first portion P1 is smaller than 0.2 times the area of each of the first opening OP1 and the second opening OP2-1, the inductance of the portion adjacent to the first area AR1-1 and the inductance of the portion adjacent to the first opening OP1 may be less increased, and when the area of the first portion P1 is greater than 0.3 times the area of each of the first opening OP1 and the second opening OP2-1, the inductance of the portion adjacent to the first area AR1-1 and the inductance of the portion adjacent to the first opening OP1 may be excessively increased, and thus the amount of change in the inductance may be increased. However, according to the present disclosure, the amount of increase in the inductance may be controlled by a relationship between the area of the first portion P1 and the area of each of the first opening OP1 and the second opening OP2-1. The amount of change in the inductance in the first opening OP1, the first area AR1-1, and second area AR2-1 may be relatively small. The reception signal may have the value within the correction range of the sensor driving unit 200C. Thus, the sensor driving unit 200C may correct the reception signal, and thus the sensing reliability may be improved.

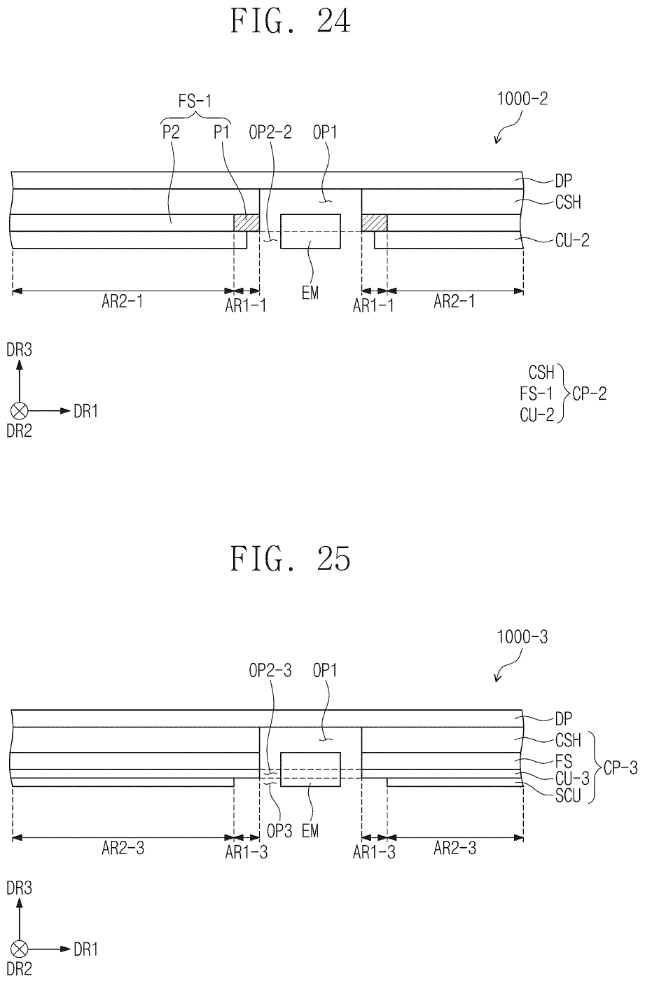

FIG. 24 is a cross-sectional view of the electronic device taken along the line corresponding to the line II-II′ of FIG. 2 according to one or more embodiments of the present disclosure. In the description of FIG. 24, the components described through FIG. 21 are designated by the same reference numerals, and a description thereof will be omitted.

Referring to FIG. 24, an electronic device 1000-2 may include the display panel DP, a cover panel CP-2, and the electronic module EM.

The cover panel CP-2 may include the cushion layer CSH, the magnetic layer FS-1, and a conductive layer CU-2. The first area AR1-1 and the second area AR2-1 may be defined in the cover panel CP-2.

A second opening OP2-2 may be defined in the conductive layer CU-2.

When viewed on a plane, the first area of the first opening OP1 may be smaller than a second area of the second opening OP2-2.

The conductive layer CU-2 may overlap a portion of the first area AR1-1 and the second area AR2-1. However, this is illustrative, and the overlapping relationship of the conductive layer CU-2 according to one or more embodiments of the present disclosure is not limited thereto. For example, the conductive layer CU-2 may overlap the second area AR2-1 and may not overlap the first area AR1-1.

The first area AR1-1 of the cover panel CP-2 may have a first magnetic permeability. The second area AR2-1 of the cover panel CP-2 may have a second magnetic permeability that is smaller than the first magnetic permeability.

FIG. 25 is a cross-sectional view of the electronic device taken along the line corresponding to the line II-II′ of FIG. 2 according to one or more embodiments of the present disclosure. In the description of FIG. 25, the components described through

FIG. 17 are designated by the same reference numerals, and a description thereof will be omitted.

Referring to FIG. 25, an electronic device 1000-3 may include the display panel DP, a cover panel CP-3, and the electronic module EM.

The cover panel CP-3 may include the cushion layer CSH, the magnetic layer FS, a conductive layer CU-3, and a sub-conductive layer SCU. A first area AR1-3 and a second area AR2-3 may be defined in the cover panel CP-3.

The first area AR1-3 may be adjacent to the electronic module EM. When viewed on a plane, the first area AR1-3 may be around (e.g., may surround) the electronic module EM.

The second area AR2-3 may cover the first area AR1-3. The second area AR2-3 may be around (e.g., may surround) the first area AR1-3. The second area AR2-3 may be spaced (e.g., spaced apart) from the first opening OP1 with the first area AR1-3 interposed therebetween.

When viewed on a plane, the first area AR1-3 may be defined between the second area AR2-3 and the first opening OP1.

A second opening OP2-3 may be defined in the conductive layer CU-3.

When viewed on a plane, the first area of the first opening OP1 may be same as a second area of the second opening OP2-3.

The sub-conductive layer SCU may be disposed under the conductive layer CU-3. When viewed on a plane, a third opening OP3 having an area larger than that of the second opening OP2-3 may be defined in the sub-conductive layer SCU.

The first area AR1-3 of the cover panel CP-3 may have a first magnetic permeability. The second area AR2-3 of the cover panel CP-3 may have a second magnetic permeability that is smaller than the first magnetic permeability.

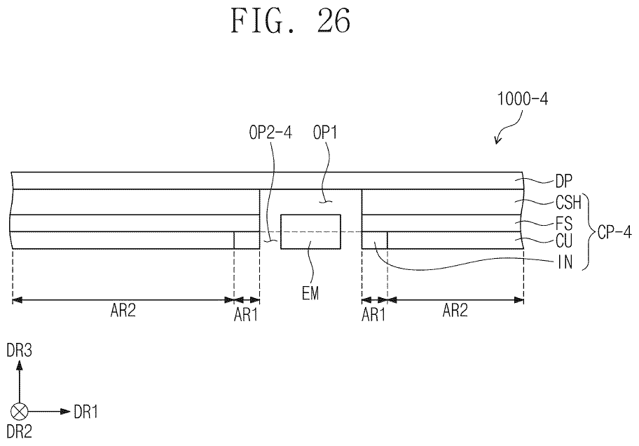

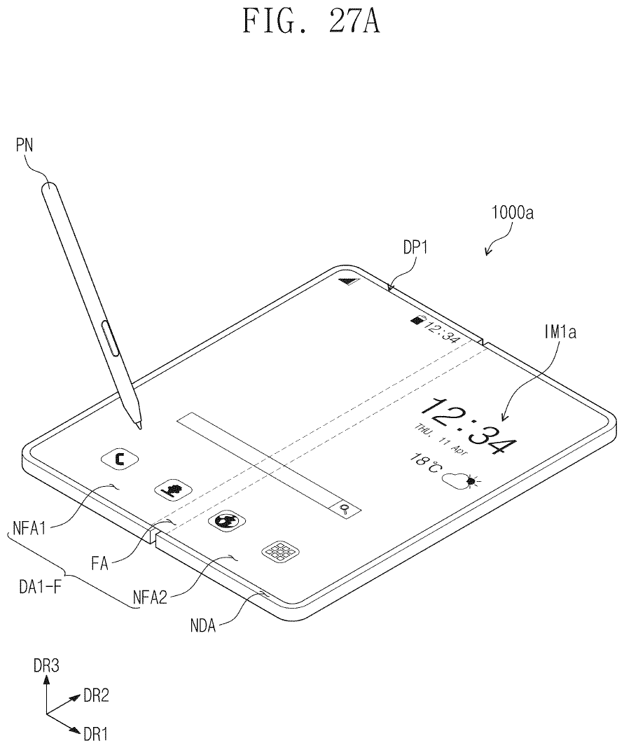

FIG. 26 is a cross-sectional view of the electronic device taken along the line corresponding to the line II-II′ of FIG. 2 according to one or more embodiments of the present disclosure. In the description of FIG. 26, the components described through

FIG. 17 are designated by the same reference numerals, and a description thereof will be omitted.

Referring to FIG. 26, an electronic device 1000-4 may include the display panel DP, a cover panel CP-4, and the electronic module EM.

The cover panel CP-4 may include the cushion layer CSH, the magnetic layer FS, the conductive layer CU, and an insulating layer IN. The first area AR1 and the second area AR2 may be defined in the cover panel CP-4.

The insulating layer IN may be disposed on (or at) the same layer as the conductive layer CU. When viewed on a plane, the insulating layer IN may overlap the first area AR1. A second opening OP2-4 may be defined by the insulating layer IN.

The first area AR1 of the cover panel CP-4 may have a first magnetic permeability. The second area AR2 of the cover panel CP-4 may have a second magnetic permeability that is smaller than the first magnetic permeability.

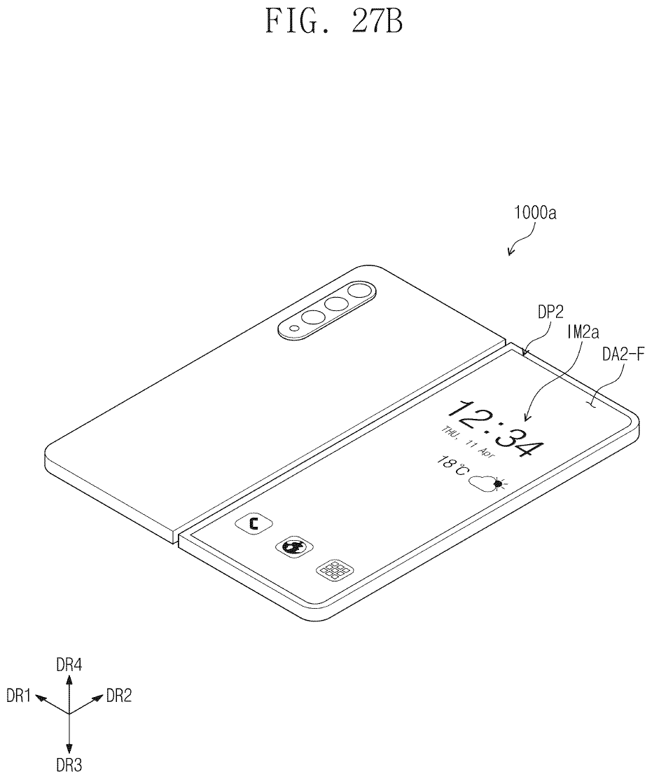

FIG. 27A is a perspective view of the electronic device according to one or more embodiments of the present disclosure, and FIG. 27B is a rear perspective view of the electronic device according to one or more embodiments of the present disclosure.

Referring to FIGS. 27A and 27B, an electronic device 1000a may be a device that is activated according to an electrical signal. For example, the electronic device 1000a may display an image and sense inputs applied from the outside. The external input may be an input of the user. The input of the user may include various types of external inputs such as the portion of the human body of the user, the pen PN, the light, the heat, or the pressure. The pen PN may be referred to as the input device PN.

The electronic device 1000a may include a first display panel DP1 and a second display panel DP2. The first display panel DP1 and the second display panel DP2 may be separate panels separated from each other. The first display panel DP1 may be referred to as a main display panel, and the second display panel DP2 may be referred to as an auxiliary display panel or an external display panel.

The first display panel DP1 may include the first display unit DA1-F, and the second display panel DP2 may include a second display unit DA2-F. An area of the second display panel DP2 may be smaller than an area of the first display panel DP1.

To correspond to the sizes of the first display panel DP1 and the second display panel DP2, an area of the first display unit DA1-F may be larger than an area of the second display unit DA2-F.

In a state in which the electronic device 1000a is unfolded, the first display unit DA1-F may have a plane substantially parallel to the first direction DR1 and the second direction DR2. A thickness direction of the electronic device 1000a may be parallel to the third direction DR3 intersecting the first direction DR1 and the second direction DR2. Thus, front surfaces (or upper surfaces) and rear surfaces (or lower surfaces) of members constituting the electronic device 1000a may be defined based on the third direction DR3.

The first display panel DP1 or the first display unit DA1-F may include a folding area FA that is folded or unfolded and a plurality of non-folding areas NFA1 and NFA2 spaced (e.g., spaced apart) from each other with the folding area FA interposed therebetween. The second display panel DP2 may overlap one of the plurality of non-folding areas NFA1 and NFA2. For example, the second display panel DP2 may overlap the first non-folding area NFA1.

A display direction of a first image IM1a displayed on a portion of the first display panel DP1, for example, the first non-folding area NFA1, may be opposite to a display direction of a second image IM2a displayed on the second display panel DP2. For example, the first image IM1a may be displayed in the third direction DR3, and the second image IM2a may be displayed in a fourth direction DR4 that is opposite to the third direction DR3.

In one or more embodiments of the present disclosure, the folding area FA may be bent with respect to a folding axis extending in a direction parallel to long sides of the electronic device 1000a, for example, a direction parallel to the second direction DR2. In a state in which the electronic device 1000a is folded, the folding area FA has a suitable curvature (e.g., a predetermined curvature) and a suitable radius (e.g., a predetermined radius) of curvature. The first non-folding area NFA1 and the second non-folding area NFA2 may face each other, and the electronic device 1000a may be inner-folded so that the first display unit DA1-F is prevented from being exposed to the outside.

In one or more embodiments of the present disclosure, the electronic device 1000a may be outer-folded so that the first display unit DA1-F is exposed to the outside. In one or more embodiments of the present disclosure, the electronic device 1000a may be both inner-folded or outer-folded in an unfolded state, but the present disclosure is not limited thereto.

FIG. 27A illustrates, as an example, that the one folding area FA is defined in the electronic device 1000a, but the present disclosure is not limited thereto. For example, a plurality of folding axes and a plurality of folding areas corresponding thereto may be defined in the electronic device 1000a, and the electronic device 1000a may be inner-folded or outer-folded in an unfolded state in each of the plurality of folding areas.

According to one or more embodiments of the present disclosure, even when at least one of the first display panel DP1 and the second display panel DP2 does not include a digitizer, the at least one of the first display panel DP1 and the second display panel DP2 may sense an input by the pen PN. Thus, because the digitizer for sensing the pen PN is omitted, an increase in a thickness, an increase in a weight, and a decrease in flexibility of the electronic device 1000a caused by addition of the digitizer may not occur. Thus, the second display panel DP2 as well as the first display panel DP1 may be designed to sense the pen PN.

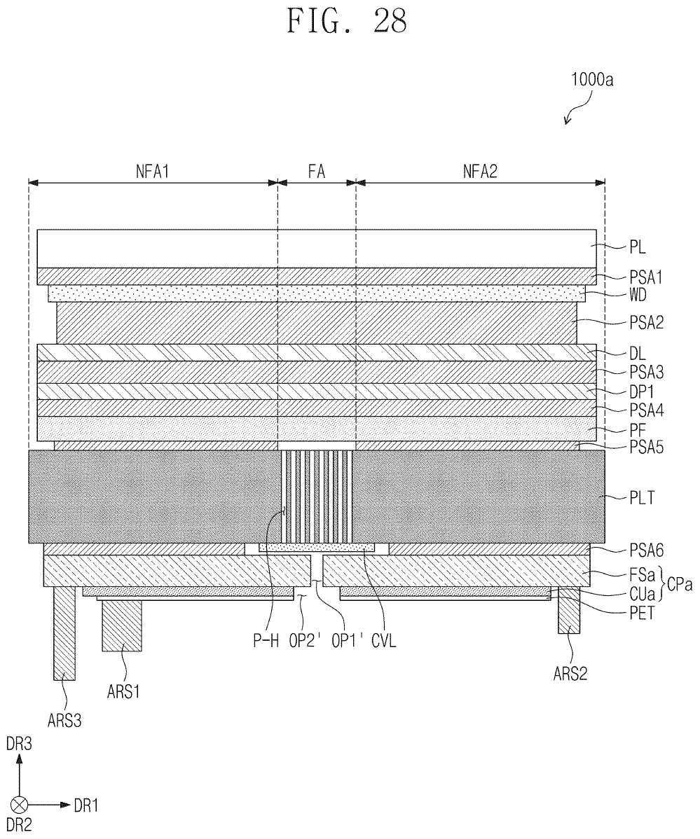

FIG. 28 is a cross-sectional view of the electronic device according to one or more embodiments of the present disclosure.

Referring to FIG. 28, the electronic device 1000a may include the first display panel DP1, upper functional layers, and lower functional layers. The upper functional layers may include components arranged on the first display panel DP1, and the lower functional layers may include components arranged under the first display panel DP1.

The first display panel DP1 may be configured to generate an image and sense an external input. For example, the first display panel DP1 may include the display layer 100 (see FIG. 5) and the sensor layer 200 (see FIG. 5).

The upper functional layers may include a protective layer PL, a window WD, an impact absorbing layer DL, and first to third adhesive layers PSA1, PSA2, and PSA3. Components included in the upper functional layers are not limited to the above-described components. At least some of the above-described components may be omitted, and other components may be added.

The protective layer PL may protect components arranged under the protective layer PL. A thickness of the protective layer PL may be 60 micrometers to 70 micrometers, for example, 65 micrometers, but the thickness of the protective layer PL is not limited thereto.

The protective layer PL may be additionally provided with a hard coating layer, a fingerprint preventing layer, and/or the like to improve properties such as chemical resistance and abrasion resistance. For example, the hard coating layer may be a functional layer for improving using characteristics of the electronic device 1000a and may be provided by coating on the protective layer PL. For example, fingerprint preventing characteristics, contamination preventing characteristics, scratch preventing characteristics, and/or the like may be improved by the hard coating layer. For example, a thickness of the hard coating layer may be 5 micrometers, but the present disclosure is not particularly limited thereto.

The window WD may be disposed under the protective layer PL. The first adhesive layer PSA1 may be disposed between the window WD and the protective layer PL. A thickness of the first adhesive layer PSA1 may be 30 micrometers to 40 micrometers, for example, 35 micrometers, but the thickness of the first adhesive layer

PSA1 is not limited thereto. In one or more embodiments of the present disclosure, a bezel pattern may be disposed between the first adhesive layer PSA1 and the protective layer PL.

The window WD may include an optically transparent insulating material. For example, the window WD may include a glass substrate and/or a synthetic resin film. The window WD may have a multi-layer structure or a single-layer structure. For example, the window WD may include a plurality of synthetic resin films coupled with an adhesive or include a glass substrate and a synthetic resin film coupled with an adhesive. When the window WD is the glass substrate, a thickness of the window WD may be 80 micrometers or less, for example, 30 micrometers, but the thickness of the window WD is not limited thereto.

The impact absorbing layer DL may be disposed under the window WD. The second adhesive layer PSA2 may be disposed between the window WD and the impact absorbing layer DL. A thickness of the second adhesive layer PSA2 may be 70 micrometers to 80 micrometers, for example, 75 micrometers, but the thickness of the second adhesive layer PSA2 is not limited thereto.

The impact absorbing layer DL may absorb an impact applied to the first display panel DP1 to protect the first display panel DP1. The impact absorbing layer DL may be manufactured in the form of a stretched film. For example, the impact absorbing layer DL may include a flexible plastic material. The flexible plastic material may be defined as a synthetic resin film. For example, the impact absorbing layer DL may include a flexible plastic material such as polyimide and/or polyethylene terephthalate. A thickness of the impact absorbing layer DL may be 18 micrometers to 28 micrometers, for example, 23 micrometers, but the thickness of the impact absorbing layer DL is not limited thereto. In one or more embodiments of the present disclosure, the impact absorbing layer DL may be omitted.

The third adhesive layer PSA3 may be disposed between the impact absorbing layer DL and the first display panel DP1. A thickness of the third adhesive layer PSA3 may be 45 micrometers to 55 micrometers, for example, 50 micrometers, but the thickness of the third adhesive layer PSA3 is not limited thereto.

The lower functional layers may include the protective film PF, a plate PLT, a cover layer CVL, a cover panel CPa, an insulating film PET, step compensation members ARS1, ARS2, and ARS3, and fourth to sixth adhesive layers PSA4, PSA5, and PSA6. Components included in the lower functional layers are not limited to the above-described components. At least some of the above-described components may be omitted, and other components may be added.

The protective film PF may be coupled to a rear surface of the first display panel DP1 through the fourth adhesive layer PSA4. A thickness of the fourth adhesive layer PSA4 may be 20 micrometers to 30 micrometers, for example, 25 micrometers, but the thickness of the fourth adhesive layer PSA4 is not limited thereto.

The protective film PF may prevent scratches from occurring on the rear surface of the first display panel DP1 during a process of manufacturing the first display panel DP1. The protective film PF may be a colored polyimide film. For example, the protective film PF may be an opaque yellow film, but the present disclosure is not limited thereto. A thickness of the protective film PF may be 45 micrometers to 55 micrometers, for example, 50 micrometers, but the thickness of the protective film PF is not limited thereto.

The plate PLT may be disposed under the protective film PF. The fifth adhesive layer PSA5 may be disposed between the plate PLT and the protective film PF. A thickness of the fifth adhesive layer PSA5 may be 11 micrometers to 21 micrometers, for example, 16 micrometers, but the thickness of the fifth adhesive layer PSA5 is not limited thereto.

The plate PLT may include carbon fiber reinforced plastic (CFRP), metal, and/or metal alloy. The plate PLT may support components arranged on the upper side. Openings P-H may be defined (formed or provided) in a portion of the plate PLT. For example, the plate PLT may include the openings P-H having a shape that passes from an upper surface to a lower surface of the plate PLT. The openings P-H may be defined in an area that overlaps the folding area FA. When viewed on a plane, for example, in the third direction DR3 or in a thickness direction of the plate PLT, the openings P-H may overlap the folding area FA. A shape of a portion of the plate PLT may be more easily deformed by the openings P-H. A thickness of the plate PLT may be 160 micrometers to 180 micrometers, for example, 170 micrometers, but the thickness of the plate PLT is not limited thereto.

The cover layer CVL may be attached to the plate PLT. The cover layer CVL may cover the openings P-H of the plate PLT. Thus, the cover layer CVL may prevent foreign substances from being introduced into the openings P-H. The cover layer CVL may include thermoplastic polyurethane, but the present disclosure is not particularly limited thereto. A thickness of cover layer CVL may be 11 micrometers to 21 micrometers, for example, 16 micrometers, but the thickness of the cover layer CVL is not limited thereto.

The cover panel CPa may include a magnetic layer FSa and a conductive layer CUa.

The magnetic layer FSa may be disposed under the plate PLT and the cover layer CVL. The sixth adhesive layer PSA6 may be disposed between the magnetic layer FSa and the plate PLT. A thickness of the sixth adhesive layer PSA6 may be 15 micrometers to 25 micrometers, for example, 20 micrometers, but the thickness of the sixth adhesive layer PSA6 is not limited thereto.

The magnetic layer FSa may shield a magnetic field that passes through the first display panel DP1. A thickness of the magnetic layer FSa may be 53 micrometers to 63 micrometers, for example, 58 micrometers, but the thickness of the magnetic layer FSa is not limited thereto.

A first opening OP1′ may be defined in the magnetic layer FSa. The conductive layer CUa may be disposed under the magnetic layer FSa. A thickness of the conductive layer CUa may be 15 micrometers to 25 micrometers, for example, 20 micrometers, but the thickness of the conductive layer CUa is not limited thereto.

A second opening OP2′ may be defined in the conductive layer CUa.

When viewed on a plane, a first area of the first opening OP1′ may be smaller than a second area of the second opening OP2′. When viewed on a plane, the first opening OP1′ and the second opening OP2′ may overlap the folding area FA.

A first magnetic permeability of a first area that overlaps the second opening OP2′ of the cover panel CPa may be higher than a second magnetic permeability of a second area that overlaps the magnetic layer FSa and the conductive layer CUa of the cover panel CPa.

According to the present disclosure, a magnetic permeability of the first area adjacent to the folding area FA may be higher than a magnetic permeability of the second area. Therefore, the amount of change in an inductance for a magnetic field emitted by the pen PN (see FIG. 27A) in the folding area FA and an area adjacent to the folding area FA may be decreased. Therefore, sensing reliability in one area of the sensor layer 200 (see FIG. 5), which overlaps the folding area FA, may be improved. Linearity of the input by the pen PN (see FIG. 27A) may be improved. Thus, the electronic device 1000a having improved sensing reliability may be provided.

The insulating film PET may be disposed under the conductive layer CUa. The insulating film PET may include polyethylene terephthalate, but the present disclosure is not particularly limited thereto. The insulating film PET may prevent inflow of static electricity. For example, the insulating film PET may prevent electrical interference between members arranged on the insulating film PET and members disposed under the insulating film PET. A thickness of the insulating film PET may be 3 micrometers to 9 micrometers, for example, 6 micrometers, but the thickness of the insulating film PET is not limited thereto.

The step compensation members ARS1, ARS2, and ARS3 may include the first step compensation member ARS1 attached to the insulating film PET, the second step compensation member ARS2 attached to the magnetic layer FSa, and the third step compensation member ARS3 attached to the magnetic layer FSa. A thickness of each of the first to third step compensation members ARS1, ARS2, and ARS3 may be variously set according to a product structure and/or a component arrangement relationship. For example, the thickness of the first step compensation member ARS1 may be 90 micrometers, the thickness of the second step compensation member ARS2 may be 87 micrometers, and the third step compensation member ARS3 may be 87 micrometers, but the present disclosure is not limited thereto.

Further, in one or more embodiments of the present disclosure, each of the sixth adhesive layer PSA6, the magnetic layer FSa, the conductive layer CUa, and the insulating film PET may have a separate structure in a portion that overlaps the folding area FA. For example, the sixth adhesive layer PSA6, the magnetic layer FSa, the conductive layer CUa, and the insulating film PET may each be divided into two structures that are spaced (e.g., spaced apart) from each other with a suitable gap (e.g., a predetermined gap) in a portion that overlaps the folding area FA.

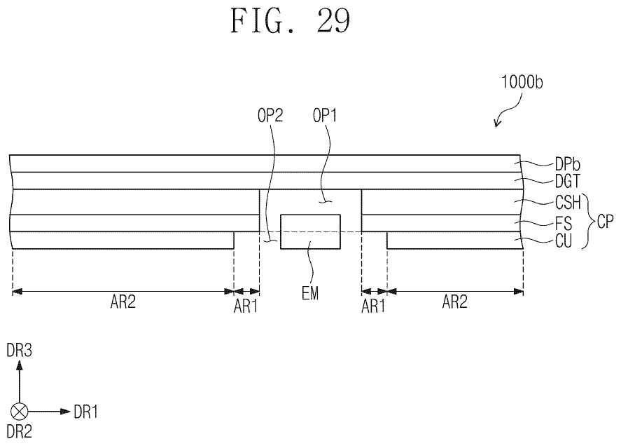

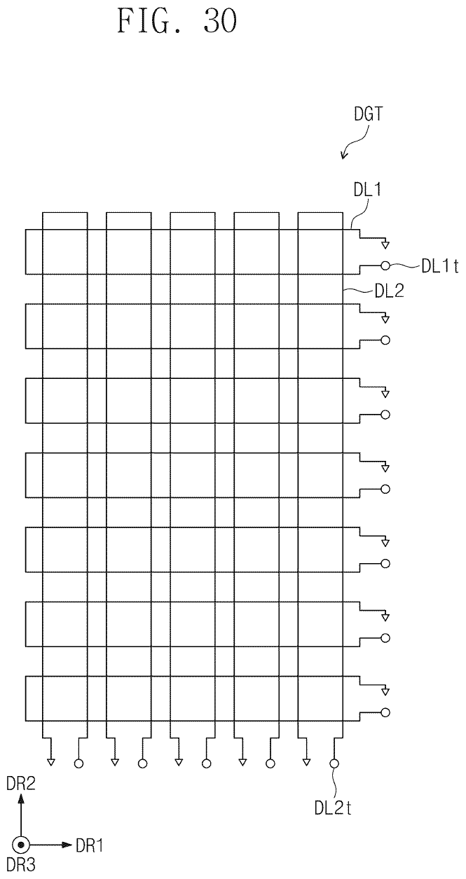

FIG. 29 is a cross-sectional view of the electronic device according to one or more embodiments of the present disclosure, and FIG. 30 illustrates an input sensor according to one or more embodiments of the present disclosure. In the description of FIG. 29, the components described through FIG. 17 are designated by the same reference numerals, and a description thereof will be omitted.

Referring to FIGS. 29 and 30, an electronic device 1000b may include a display panel DPb, an input sensor DGT, the cover panel CP, and the electronic module EM.

A sensor layer of the display panel DPb may be a component in which the plurality of third electrodes 230 (see FIG. 7) and the plurality of fourth electrodes 240 (see FIG. 7) in the sensor layer 200 (see FIG. 7) illustrated in FIG. 7 are omitted.

The input sensor DGT may be disposed under the display panel DPb. The second input 3000 (see FIG. 5) of the pen PN (see FIG. 5) may be sensed through the input sensor DGT. That is, the display panel DPb may sense the second input 3000 (see FIG. 5) through the separate input sensor DGT.

The input sensor DGT may sense an external input through electromagnetic resonance (EMR).

In the EMR manner, a magnetic field may be generated in a resonance circuit configured inside the input device PN (see FIG. 5), the oscillating magnetic field may induce a signal in a plurality of coils included in the input sensor DGT, and a position of the input device PN (see FIG. 5) may be sensed through the signal induced in the coils.

The input sensor DGT may include a plurality of first coils DL1 and a plurality of second coils DL2. The plurality of first coils DL1 may be referred to as driving coils, and the plurality of second coils DL2 may be referred to as sensing coils.

The plurality of first coils DL1 may be arranged to be insulated from and intersect the plurality of second coils DL2. To sense the input device PN (see FIG. 5), an alternating current (AC) signal may be sequentially provided to a first terminal DL1t of each of the plurality of first coils DL1. Each of the plurality of first coils DL1 may be formed in a closed curve shape, and when a current flows through each of the plurality of first coils DL1, a magnetic force line may be induced between the plurality of first coils DL1 and the plurality of second coils DL2. The plurality of second coils DL2 may output a signal obtained by sensing an induced electromagnetic force emitted from the input device PN (see FIG. 5) to a second terminal DL2t of each of the plurality of second coils DL2.

FIG. 30 illustrates as an example a configuration of the digitizer, but the present disclosure is not limited thereto. Further, an arrangement relationship between the plurality of first coils DL1 and the plurality of second coils DL2 is not limited to that illustrated in FIG. 30 and may be variously modified.

The first area AR1 of the cover panel CP may have a first magnetic permeability. The second area AR2 of the cover panel CP may have a second magnetic permeability that is smaller than the first magnetic permeability.

According to the above description, in a sensing area in which an electronic module is disposed, a magnetic layer and a conductive layer may not overlap the electronic module. A magnetic permeability of a first area adjacent to the sensing area may be higher than a magnetic permeability of a second area. Therefore, the amount of change in an inductance for a magnetic field in the sensing area and an area adjacent to the sensing area may be decreased. Therefore, sensing reliability in one area of a sensor layer, which overlaps the sensing area, may be improved. Linearity of an input by a pen may be improved. Thus, an electronic device having improved sensing reliability may be provided.

Although the description has been made above with reference to one or more embodiments of the present disclosure, it may be understood that those skilled in the art or those having ordinary knowledge in the art may variously modify and change the present disclosure without departing from the spirit and technical scope of the present disclosure described in the appended claims and their equivalents. Thus, the technical scope of the present disclosure is not limited to the detailed description of the specification but should be defined by the appended claims.

1 what is claimed is:

1. An electronic device comprising:
a display panel;
a cover panel under the display panel; and
an electronic module under the display panel,
wherein the cover panel comprises:
a cushion layer under the display panel;
a magnetic layer under the cushion layer; and
a conductive layer under the magnetic layer,
wherein a first opening is defined in the cushion layer and the magnetic layer,
wherein a second opening is defined in the conductive layer,
wherein the electronic module is located in the first opening and the second opening, and
wherein a first area adjacent to the electronic module and having a first magnetic permeability and a second area around the first area and having a second magnetic permeability different from the first magnetic permeability are defined in the cover panel.

2. The electronic device of claim 1, wherein a first area of the first opening is smaller than a second area of the second opening.

3. The electronic device of claim 2, wherein the second area is 1.5 to 1.6 times the first area.

4. The electronic device of claim 1, wherein, in a plan view, the magnetic layer covers the conductive layer.

5. The electronic device of claim 1, wherein the magnetic layer comprises ferrite, and the conductive layer comprises copper.

6. The electronic device of claim 1, wherein a magnetic permeability of the magnetic layer is higher than a magnetic permeability of the conductive layer.

7. The electronic device of claim 1, wherein, in a plan view, at least a portion of the second opening overlaps the first area.

8. The electronic device of claim 1, wherein, in a plan view, the electronic module does not overlap the magnetic layer and the conductive layer.

9. The electronic device of claim 1, wherein the electronic module comprises a fingerprint sensor.

10. The electronic device of claim 1, wherein the electronic module comprises a speaker or a photo sensor.

11. The electronic device of claim 1, wherein each of the first opening and the second opening has a circular shape.

12. The electronic device of claim 1, wherein each of the first opening and the second opening has a quadrangular shape.

13. The electronic device of claim 1, wherein the display panel comprises a display layer and a sensor layer on the display layer, and
wherein the sensor layer comprises:
a plurality of first electrodes arranged along a first direction and extending in a second direction intersecting the first direction;
a plurality of second electrodes arranged along the second direction and extending in the first direction;
a plurality of first auxiliary electrodes arranged along the first direction, extending in the second direction, and overlapping the plurality of first electrodes; and
a plurality of second auxiliary electrodes arranged along the second direction, extending in the first direction, and overlapping the plurality of second electrodes.

14. The electronic device of claim 1, wherein the magnetic layer comprises a first portion in the first area and a second portion in the second area, and
wherein a magnetic permeability of the first portion is higher than a magnetic permeability of the second portion.

15. The electronic device of claim 14, wherein areas of the first opening and the second opening are the same.

16. The electronic device of claim 14, wherein a first area of the first opening is smaller than a second area of the second opening.

17. The electronic device of claim 14, wherein an area of the first portion is 0.2 to 0.3 times an area of each of the first opening and the second opening.

18. The electronic device of claim 1, wherein, in a plan view, the conductive layer overlaps only the second area, and the magnetic layer overlaps the first area and the second area.

19. The electronic device of claim 18, wherein the cover panel further comprises an insulating layer at a same layer as the conductive layer and overlapping the first area in a plan view.

20. The electronic device of claim 1, wherein the cover panel further comprises a sub-conductive layer under the conductive layer and including a third opening having an area larger than that of the second opening.

21. An electronic device comprising:
a display panel and a cover panel under the display panel,
wherein the cover panel comprises:
a magnetic layer under the display panel and having a first opening; and
a conductive layer under the magnetic layer and having a second opening, and
wherein a first area adjacent to the first opening and the second opening and having a first magnetic permeability and a second area around the first area and having a second magnetic permeability different from the first magnetic permeability are defined in the cover panel.

22. The electronic device of claim 21, wherein a first area of the first opening is smaller than a second area of the second opening.

23. The electronic device of claim 21, wherein, in a plan view, the magnetic layer covers the conductive layer.

24. The electronic device of claim 21, wherein the magnetic layer comprises ferrite, and the conductive layer comprises copper.

25. The electronic device of claim 21, wherein the magnetic layer comprises a first portion in the first area and a second portion in the second area, and wherein a magnetic permeability of the first portion is higher than a magnetic permeability of the second portion.

26. The electronic device of claim 21, wherein, in a plan view, the conductive layer overlaps only the second area, and the magnetic layer overlaps the first area and the second area.

27. The electronic device of claim 21, wherein the display panel comprises a display layer and a sensor layer on the display layer, and
wherein the sensor layer comprises:
a plurality of first electrodes arranged along a first direction and extending in a second direction intersecting the first direction;
a plurality of second electrodes arranged along the second direction and extending in the first direction;
a plurality of first auxiliary electrodes arranged along the first direction, extending in the second direction, and overlapping the plurality of first electrodes; and
a plurality of second auxiliary electrodes arranged along the second direction, extending in the first direction, and overlapping the plurality of second electrodes.

28. The electronic device of claim 21, wherein, in a plan view, the conductive layer does not overlap the first area.

29. The electronic device of claim 21, wherein the cover panel further comprises an insulating layer on a same layer as the conductive layer and overlapping the first area in a plan view.

30. The electronic device of claim 21, wherein the cover panel further comprises a sub-conductive layer under the conductive layer and having a third opening having an area larger than that of the second opening is defined.
